(19) United States
(12) Patent Application Publication
(10) Pub. No.: US 2026/0293514 A1
(43) Pub. Date: Sep. 24, 2026

(54) NEAR-INFRARED PEROVSKITE LIGHT-EMITTING DIODES

(71) Applicant: Purdue Research Foundation, West Lafayette, IN (US)

(72) Inventors: Letian DOU, West Lafayette, IN (US); Wenhao SHAO, West Lafayette, IN (US); Sungdoo BAEK, West Lafayette, IN (US)

(73) Assignee: Purdue Research Foundation, West Lafayette, IN (US)

(21) Appl. No.: 19/034,124

(22) Filed: Jan. 22, 2025

Related U.S. Application Data
(60) Provisional application No. 63/623,554, filed on Jan. 22, 2024.

(51) Int. Cl. H10K 85/50; H10K 50/11; H10K 50/15; H10K 50/16; H10K 50/17; H10K 50/82; H10K 71/15; H10K 101/40

(52) U.S. Cl. CPC H10K 85/50; H10K 50/11; H10K 50/15; H10K 50/16; H10K 50/17; H10K 71/15; H10K 50/82; H10K 2101/40

(57) ABSTRACT

Near-infrared (NIR) perovskite light-emitting diodes (PeLEDs) and methods of formation are described. To form the PELEDs, perovskite precursors are dissolved using a mixture of N,N-dimethylformamide (DMF) and N-methylpyrrolidone (NMP) to form perovskite crystals. The perovskite crystals are modified using a small-bandgap organic cation of 2-(5-(7-(3-ethylthiophen-2-yl)-5,6-difluorobenzo[c][1,2,5]thiadiazol-4-yl)thiophen-2-yl)ethan-1-aminium iodide (TeFBTT) to form a two- or three-dimensional (2D/3D) perovskite heterostructure in a (TeFBTT)₂PbI₄ thin film. The (TeFBTT)₂PbI₄ thin film is then used to form the NIR PeLED.

### CROSS REFERENCE TO RELATED APPLICATION

This application claims the benefit of priority to U.S. Provisional Patent Application No. 63/623,554, filed Jan. 22, 2024, which is incorporated herein by reference in its entirety.

### STATEMENT OF GOVERNMENT SUPPORT

This invention was made with government support under 2131608 ECCS awarded by the National Science Foundation and under DE-EE0009519 and DE-SC0022082 awarded by the Department of Energy. The government has certain rights in the invention.

### BACKGROUND

Metal halide perovskites have garnered considerable recognition due to their optoelectronic properties, including narrow emission line width, bandgap tunability, and excellent charge transport characteristics. These advantages position them as an innovative material platform with great potential to revolutionize light-emitting diode (LED) technologies. Specifically, in the near-infrared (NIR) region (about 800 nm), perovskite LEDs (PeLEDs) have demonstrated improved performance compared to organic and quantum-dot counterparts and are promising for next-generation night vision, communication, sensing, imaging, biomedical, and therapeutical applications. However, NIR PeLEDs with external quantum efficiencies (EQEs) pinned at 23-24% still lag behind costly yet high-performing epitaxial III-V semiconductor counterparts, which usually demonstrate EQEs exceeding 30% with exceptionally high brightness. The pursuit of NIR PeLEDs with enhanced performance involves a comprehensive engineering approach that balances isolated considerations.

### SUMMARY

A method of forming a near-infrared (NIR) perovskite light emitting diode (PeLED) includes dissolving perovskite precursors using a mixture of Lewis base solvents to form perovskite crystals, the mixture of Lewis base solvents comprising N,N-dimethylformamide (DMF) and at least one other Lewis base solvent selected from a group that includes N-methylpyrrolidone (NMP), dimethyl sulfoxide (DMSO), tris(N,N-tetramethylene) phosphoric acid triamide (TPPO), hexamethyl phosphoryl triamide (HMPA), diethyl sulfoxide (DES), N,N-dimethylpropyleneurea (DMPU), 1,3-dimethyl-2-imidazolidinone (DMI), N,N-dimethylacetamide (DMA), tetramethylene sulfoxide (TMSO), and 2-pyrrolidinone (PDI); modifying the perovskite crystals using a small-bandgap organic cation of 2-(5-(7-(3-ethylthiophen-2-yl)-5,6-difluorobenzo[c][1,2,5]thiadiazol-4-yl)thiophen-2-yl)ethan-1-aminium iodide (TeFBTT) to form a two- or three-dimensional (2D/3D) perovskite heterostructure in a (TeFBTT)₂PbI₄ thin film; and fabricating the PeLED using the (TeFBTT)₂PbI₄ thin film.

A NIR PeLED contains a zinc oxide (ZnO)/polyethylenimine ethoxylated (PEIE) layer disposed on an indium-tin-oxide (ITO)-coated transparent substrate; a (TeFBTT)PbI₄ thin film disposed on the ZnO/PEIE layer; a poly(9,9-dioctylfluorene-alt-N-(4-butylphenyl)-diphenylamine) (TFB) layer disposed on the (TeFBTT)₂PbI₄ thin film; a Molybdenum oxide (MoOₓ) layer disposed on the TFB layer; and a gold (Au) layer disposed on the MoOₓ layer to form a top electrode.

Another method of forming a NIR PeLED includes dissolving perovskite precursors using a mixture of DMF and NMP in a ratio of DMF:NMP between about 10:1 to about 14:1 to form perovskite crystals; modifying the perovskite crystals using a small-bandgap organic cation of TeFBTT to form a two- or three-dimensional (2D/3D) perovskite heterostructure in a (TeFBTT)₂PbI₄ thin film; fabricating the PeLED using the (TeFBTT)₂PbI₄ thin film; and measuring a peak radiance and peak external quantum efficiency (EQE) of at least about 500 W sr⁻¹ cm⁻² and 26.5%, respectively.

Another method of forming a NIR PeLED includes dissolving perovskite precursors using a mixture of Lewis base solvents that include DMF and another Lewis base solvent in a ratio of DMF:other Lewis base solvent that is dependent on the other Lewis base solvent (e.g., a DMF:DMSO ratio of about 6:1 to about 10:1) to form perovskite crystals; modifying the perovskite crystals using a small-bandgap organic cation of TeFBTT to form a two- or three-dimensional (2D/3D) perovskite heterostructure in a (TeFBTT)₂PbI thin film; fabricating the PeLED using the (TeFBTT)₂PbI₄ thin film; and measuring a peak radiance and peak external quantum efficiency (EQE) of at least about 500 W sr⁻¹ cm⁻² and 26.5%, respectively.

As used herein, the term “Lewis base solvent” generally refers to a solvent molecule that acts as a Lewis base, meaning it has a lone pair of electrons that it can donate to another molecule (e.g., a Lewis acid); essentially, it is a solvent capable of donating electron pairs to other substances. Examples of Lewis base solvents include, but are not limited to nitriles, ethers, heterocyclic solvents, amines, alcohols, amides, esters, phosphorus-containing solvents, sulfur-containing solvents, urea-based solvents, and the like. Specific Lewis base solvents include acetonitrile, tetrahydrofuran (THF), pyridine, 1,4-diazabicyclo[2.2.2]octane (DABCO), N,N-diisopropylethylamine (DIPEA), N,N-dimethylbenzylamine (DMBA), 1,2-dimethoxyethane (DME), 1,3-bis(diphenylphosphino)propane (DPP), γ-butyrolactone, and the like. Specific Lewis base solvents include N-methylpyrrolidone (NMP), dimethyl sulfoxide (DMSO), tris(N,N-tetramethylene) phosphoric acid triamide (TPPO), hexamethyl phosphoryl triamide (HMPA), diethyl sulfoxide (DES), N,N-dimethylpropyleneurea (DMPU), 1,3-dimethyl-2-imidazolidinone (DMI), N,N-dimethylacetamide (DMA), tetramethylene sulfoxide (TMSO), and 2-pyrrolidinone (PDI).

Examples of nitrile solvents include benzonitrile, propionitrile, 3-methoxypropionitrile, 3,3′-oxydipropionitrile, methoxyacetonitrile, pimelonitrile, phenylacetonitrile, glutaronitrile, ethyle glycol bis propionitrile, butyronitrile, and the like, such as 1,2-dimethoxyethane (DME).

Examples of ether solvents include tert-amyl ethyl ether, tert-amyl methyl ether, vyclopentyl methyl ether, di-tert-butyl ether, di(propylene glycol) methyl ether, dibutyl ether, diethyl ether, diisopropyl ether, dimethoxyethane, dimethoxymethane, 1,4-dioxane, ethyl tert-butyl ether, methoxyethane, 2-(2-methoxyethoxy)ethanol, methyl tert-butyl ether, morpholine, polyethylene glycol, propylene glycol methyl ether, and the like.

Examples of heterocyclic solvents include lutidine, morpholine, piperidine, pyrrolidine, quinoline, tetrahydroquinoline, and the like, such as pyridine, 1,4-diazabicyclo[2.2.2]octane (DABCO), N-methylpyrrolidone (NMP), γ-butyrolactone, 2-pyrrolidinone (PDI), 1,3-dimethyl-2-imidazolidinone (DMI), N-vinylpyrrolidone, tetrahydrofurfuryl alcohol, tetrahydropyran, 2,2,5,5-tetramethyltetrahydrofuran, 2-methyltetrahydrofuran, and the like, such as tetrahydrofuran (THF), N-methyl-2-pyrrolidone, 2-pyrrolidone, N-methyl-2-pyrrolidone, and N-formylmorpholine.

Examples of amine solvents include collidine, diethylenetriamine, ethylenediamine, tributylamine, and the like, such as N,N-diisopropylethylamine (DIPEA), and N,N-dimethylbenzylamine (DMBA).

Examples of alcohol solvents include tert-amyl alcohol, benzyl alcohol, 1,4-butanediol, 1,2,4-butanetriol, butanol, 1-butanol, 2-butanol, tert-butyl alcohol, denatured alcohol, di(propylene glycol) methyl ether, diethylene glycol, ethanol, ethylene glycol, 2-ethylhexanol, furfuryl alcohol, glycerol, isobutanol, isopropyl alcohol, methanol, 2-(2-methoxyethoxy)ethanol, 2-methyl-1-butanol, 2-methyl-1-pentanol, 3-methyl-2-butanol, neopentyl alcohol, 2-pentanol, 1,3-propanediol, 1-propanol, propylene glycol, propylene glycol methyl ether, and the like.

Examples of amide solvents include diethylformamide, formamide, N-methylformamide, N,N-dimethylacetamide (DMA), N-vinylacetamide, and the like.

Examples of ester solvents include benzyl benzoate, bis(2-ethylhexyl) adipate, bis(2-ethylhexyl) phthalate, bis(2-ethylhexyl) terephthalate, 2-butoxyethanol acetate, butyl acetate, sec-butyl acetate, tert-butyl acetate, diethyl carbonate, dimethyl adipate, ethyl acetate, ethyl acetoacetate, ethyl butyrate, ethyl lactate, ethylene carbonate, hexyl acetate, isoamyl acetate, isobutyl acetate, isopropyl acetate, methyl acetate, methyl acetoacetate, methyl lactate, methyl phenylacetate, methyl propionate, propyl acetate, propylene carbonate, triacetin, and the like.

Examples of phosphorus-containing solvents include tris(N,N-tetramethylene) phosphoric acid triamide (TPPO), hexamethyl phosphoryl triamide (HMPA), 1,3-bis(diphenylphosphino)propane (DPPP), and the like.

Examples of sulfur-containing solvents include and dimethyl sulfoxide (DMSO), diethyl sulfoxide (DES), tetramethylene sulfoxide (TMSO), and the like.

Examples of urea-based solvents include N,N-dimethylpropyleneurea (DMPU), 1,1-dimethylurea, tetramethylurea, and the like.

### DESCRIPTION OF THE DRAWINGS

The drawings illustrate generally, by way of example, but not by way of limitation, various embodiments discussed herein.

FIG. 1A shows scanning electron microscopy (SEM) images and atomic force microscopy (AFM) height profiles of perovskite films with varying solvent mixing ratios.

FIG. 1B shows a device structure.

FIG. 1C shows current density-voltage-radiance (J-V-R) curves of PeLEDs based on perovskite films with varying solvent mixing ratios.

FIG. 1D shows EQE characteristics of perovskite light-emitting diodes (PeLEDs) based on perovskite films with varying solvent mixing ratios.

FIGS. 1E-1H show perovskite film and PeLED characteristics in which FIG. 1E shows powder X-ray diffraction (PXRD) spectra, FIG. 1F shows photoluminescence (PL) spectra of perovskite films with varying solvent mixing ratios, FIG. 1G shows a cross-sectional SEM image of the fabricated PeLED with DMF:NMP=10:1 condition, and FIG. 1H shows electroluminescence (EL) spectra of PeLEDs with control and solvent-engineered (DMF:NMP=10:1) film.

FIGS. 2A-2S show the molecular design aspects of TeFBTT and the PeLED performance after TeFBTT incorporation, where the tailor-designed cation TeFBTT iodide salt stands for 2-(5-(7-(3-ethylthiophen-2-yl)-5,6-difluorobenzo[c][1,2,5]thiadiazol-4-yl) thiophen-2-yl)ethan-1-aminium iodide; FIG. 2A shows the chemical structure of TeFBTT and single crystal structure of (TeFBTT)₂PbI₄; FIG. 2B shows a schematic representation of the TeFBTT-incorporated 2D/3D perovskite heterostructure;

FIG. 2C shows a grazing incidence wide angle X-ray scattering (GIWAXS) pattern of a perovskite film with TeFBTT post-treatment; FIG. 2D shows an EQEₘₐₓ of PeLEDs with different conditions; FIG. 2E shows EL spectra and a camera image of the light emission from the device; FIG. 2F shows J-V-R curves; FIG. 2G shows EQE characteristics of PeLEDs with solvent-engineered and TeFBTT-treated perovskite films; FIG. 2H shows histograms depicting EQEₘₐₓ of PeLEDs; FIG. 2I shows EQEₘₐₓ based on the data presented in Table 1, FIG. 2J shows an energy band diagram of [PbI₄]²⁻ and TeFBTT with calculated and experimental values; FIG. 2K shows secondary electron cutoff; FIG. 2L shows valence band edge spectra of TeFBTT; FIG. 2M shows absorption spectra; FIG. 2N shows PL spectra of (TeFBTT)₂PbI₄ film and TeFBTT itself, FIG. 2O shows experimental and calculated PXRD spectra of (TeFBTT)₂PbI₄ films; FIG. 2P shows J-V-R curves of PeLEDs with varying TeFBTT concentrations; FIG. 2Q shows the EQE of PeLEDs with varying TeFBTT concentrations; FIG. 2R shows a SEM image of perovskite films with optimized TeFBTT concentration (0.02% w/v); FIG. 2S shows PL spectra of perovskite films with solvent-engineered and TeFBTT-treated conditions.

FIGS. 3A-3H show cross-validation of PeLEDs in which FIG. 3A shows a schematic representation for angle-dependent EQE measurement conducted at a cross-validation institution, along with a camera image of the tested device, FIG. 3B shows J-V-R curves, FIG. 3C shows EQE characteristics of the device for the cross-validation, FIG. 3D shows a schematic representation of the integrating sphere in our measurement system, accompanied by a camera image of the tested device, FIG. 3E shows J-V-R curves of the device, FIG. 3F shows EQE characteristics of the device, FIG. 3G shows EL spectrum, and FIG. 3H shows ideal Lambertian profile with experimental angular emission data of the cross-validated PeLED.

FIGS. 4A-4E characterize the origin of high performance from the PeLEDs from various aspects. FIGS. 4A-4B characterize the light outcoupling under 3D Finite-Difference Time-Domain (3D-FDTD) simulation in which FIG. 4A shows a model device structure with single grain cell for outcoupling efficiency simulation, FIG. 4B shows simulated relative outcoupling efficiencies of perovskite films with varying convex height (hₛ). FIG. 4C shows excitation power-dependent average PL quantum yields (PLQYs) (shadow region: standard deviation), FIG. 4D shows time-resolved PL (TRPL) spectra. FIG. 4E shows nanoscale charge-carrier recombination lifetime mapping (100 nm×100 nm) and corresponding AFM images (inset) of perovskite films with control, solvent-engineered, and TeFBTT-treated condition (scale bar: 20 nm).

FIG. 5 shows AFM tomography of perovskite films with different solvent mixing ratios with line profiles included under each image.

FIG. 6 shows GIWAXS patterns of perovskite films treated with different TeFBTT concentrations.

FIGS. 7A-7F show PeLEDs with wide band-gap organic cations, in which FIG. 7A shows chemical structure of PEAI and energy band diagram of [PbI₄]²⁻ and PEAI, FIG. 7B and FIG. 7C show J-V-R curves and EQE characteristics of PeLEDs with PEAI, FIG. 7D shows chemical structure of 3TI and energy band diagram of [PbI₄]²⁻ and 3TI, FIG. 7E and FIG. 7F show J-V-R curves and EQE characteristics of PeLEDs with 3TI.

FIG. 8A and FIG. 8B, respectively, show J-V-R curves and EQE characteristics of two other representative TeFBTT-treated PeLEDs.

FIG. 9 shows the operational lifetime of PeLEDs at different current densities.

FIGS. 10A-10C show the discrete island-convex dome morphology under SEM and AFM, in which FIG. 10A shows cross-sectional SEM images of PeLEDs with varying solvent mixing ratios (scale bar: 400 nm), FIG. 10B shows AFM images, and FIG. 10C shows the height profiles of poly(9,9-dioctylfluorene-alt-N-(4-butylphenyl)-diphenylamine) (TFB) on perovskite films with varying solvent mixing ratios.

FIG. 11 shows refractive index spectra of layers in PeLEDs obtained by ellipsometry, 3D-FDTD outcoupling efficiency simulation in FIGS. 4A-4B was based on refractive indices at 800 nm.

FIGS. 12A-12C respectively show histograms of nanoscale charge-carrier recombination lifetime mapping for control, solvent-engineered, and TeFBTT-treated films perovskite films, which are related to FIG. 4E.

FIG. 13 shows the solution chemistry of precursor solutions involving the 5-aminovaleric acid (5AVA) additive, which involves a competition between ring-closure lactam formation and the reaction between 5AVA and formamidinium iodide (FAI) to form gaseous ammonia.

FIG. 14 shows formation of 2-piperidone from 5AVA probed with gas chromatography/mass spectrometry (GC/MS).

FIG. 15 shows NMR spectra of 5AVA in DMSO and its lactam forming self-reaction in which the ¹H spectra were obtained before the complete reaction, while the ¹³C spectrum was obtained after the complete reaction.

FIG. 16 shows an ammonia-producing reaction between FAI and 5AVA in DMSO probed with (top) pH strips and (bottom) production of white fume with HCl vapor.

FIGS. 17-19 show the data processing procedures for AFM and SEM images to obtain the H and α of perovskite films, in which FIG. 17 shows the processing process of AFM images with a representative topography from DMF:NMP=10:1. FIG. 18 shows a representative line profile extracted from topography AFM image of TFB on perovskite with the DMF condition. FIG. 19 shows topography images obtained from SEM processed via particle analyses.

FIG. 20 shows a synthetic scheme for TeFBTT.

FIG. 21A and FIG. 21B respectively shows the structure and 1H NMR spectra of 2-bromo-3-ethylthiophene.

FIG. 22A and FIG. 22B, respectively, show the structure and 1H NMR spectra of tert-butyl(2-(5-(7-(3-ethylthiophen-2-yl)-5,6-difluorobenzo[c][1,2,5]thiadiazol-4-yl)thiophen-2-yl)ethyl)carbamate (TeFBTT-Boc).

FIG. 23A and FIG. 23B, respectively, shows the structure and ¹H NMR spectra of tert-butyl(2-(5-(7-bromo-5,6-difluorobenzo[c][1,2,5]thiadiazol-4-yl)thiophen-2-yl)eth yl)carbamate (BrFBTT-Boc).

FIG. 24A and FIG. 24B, respectively, shows the structure and ¹H NMR spectra of TeFBTT.

FIG. 25A and FIG. 25B, respectively, shows the structure and ¹³C NMR spectra of TeFBTT.

FIG. 26 shows a device in accordance with some examples.

FIG. 27 illustrates an example of an electronic device in accordance with some embodiments.

FIG. 28A, FIG. 28B, and FIG. 28C, respectively, shows SEM images of perovskite films using DMF and DMSO solvent mixtures with different mixing ratios, J-V-R curves of PeLEDs with varying DMF and DMSO solvent mixing ratios, and EQE of PeLEDs with varying DMF and DMSO solvent mixing ratios.

### DESCRIPTION

Reference will now be made in detail to certain embodiments of the disclosed subject matter. While the disclosed subject matter will be described in conjunction with the enumerated claims, it will be understood that the exemplified subject matter is not intended to limit the claims to the disclosed subject matter.

Highly efficient NIR PeLEDs are described herein. The NIR PeLEDs are based on cubic-phase formamidinium lead triiodide (α-FAPbI₃) having enhancements in outcoupling efficiency, defect passivation, and rapid radiative recombination. The NIR PeLEDs have a peak EQE of 29.0% (average 26.3%) and a maximum radiance of 929 W sr⁻¹m⁻². Solvent-engineering and two-dimensional/three-dimensional (2D/3D) perovskite heterostructures are used to obtain the NIR PeLED characteristics. Solvent engineering enabled delicate control over discontinuous film morphology towards amplified outcoupling efficiency and facilitated passivation over crystal defects and radiative recombination. Subsequently, the as-grown perovskite crystals were modified with a small-bandgap organic cation of 2-(5-(7-(3-ethylthiophen-2-yl)-5,6-difluorobenzo[c][1,2,5]thiadiazol-4-yl)thiophen-2-yl)ethan-1-aminium iodide (TeFBTT). One role of TeFBTT involves forming a 2D/3D heterostructure on the surface of FAPbI₃ to facilitate defect passivation and radiative recombination simultaneously and elevate the efficiency of the NIR PeLEDs.

### Discontinuous Polycrystalline Films Through Solvent Engineering

In a solvent engineering approach, a mixture of N,N-dimethylformamide (DMF) and N-methylpyrrolidone (NMP) was used to dissolve the perovskite precursors. The addition of NMP in DMF may yield a significantly more stable α-FAPbI₃ phase with fewer defects, achieved through the formation of a stable intermediate phase that facilitates the control of nucleation and crystal growth.

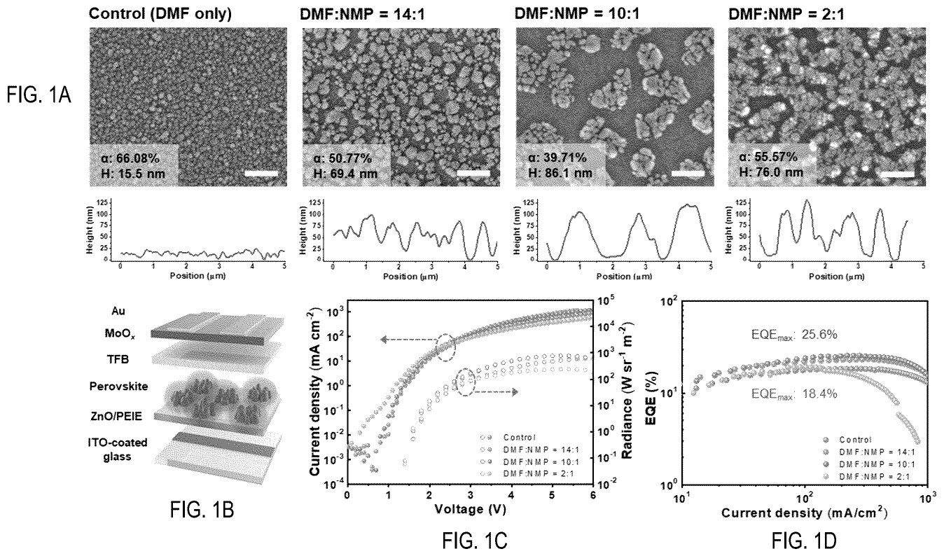

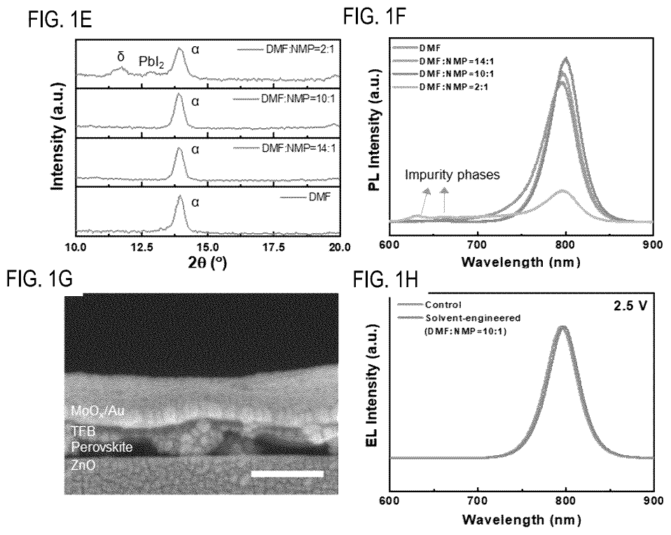

FIGS. 1A-1H show aspects of a perovskite film and PeLED characteristics. FIG. 1A shows scanning electron microscopy (SEM) images and atomic force microscopy (AFM) height profiles of perovskite films with varying solvent mixing ratios. The packing density (α) and average height (H) were respectively obtained from SEM and AFM. The scale bars are 1 μm. FIG. 1A thus displays the morphology of polycrystalline FAPbI₃ films obtained with gradually increased NMP content in the precursor solution, examined by SEM and AFM. It is generally observed that amino acid additives—5-aminovaleric acid (5AVA) in this case—improve the formation of discontinuous FAPbI₃ islands toward better crystallinity on a zinc oxide (ZnO)/polyethyleneimine ethoxylated (PEIE) layer. This phenomenon becomes more pronounced with the addition of NMP, primarily attributed to its discernibly higher boiling point compared with DMF, resulting in larger crystal grains. Therefore, compared with the control sample fabricated with a pure DMF solution, increasing the NMP ratio in DMF through 14:1 to 10:1 led to gradually increased average grain size along with decreased packing density. However, crystals became more aggregated when an excess amount of NMP was introduced, reaching a ratio of 2:1 (DMF:NMP), as shown in FIG. 1A. FIG. 1B shows a device structure. FIG. 1C shows J-V-R curves. FIG. 1D shows EQE characteristics of PeLEDs based on perovskite films with varying solvent mixing ratios.

To investigate the influence of NMP on crystal phase and quality, powder X-ray diffraction (PXRD) (FIG. 1E) and photoluminescence (PL) analyses (FIG. 1F) were performed. All films exhibited strong diffraction peaks from α-FAPbI₃ without impurity phases except for the condition of DMF:NMP=2:1, where 8-FAPbI₃ and PbI₂ are evident. This implies that an excessive amount of NMP hinders the crystallization toward the desired α-FAPbI₃, which in turn leads to weak desired NIR emission and multiple impurity PL peaks (as shown in FIG. 1F). The appropriate amount of NMP, on the other hand, can lead to enhanced PL and a narrower peak compared to the use of pure DMF (full width at half maximum, FWHM ~45 nm). Specifically, the DMF:NMP=10:1 solution led to perovskites that exhibited the highest PL intensity at 800 nm with a narrower peak (FWHM ~41 nm). FIG. 1G shows a cross-sectional SEM image of the fabricated PeLED with DMF:NMP=10:1 condition (scale bar: 200 nm) and FIG. 1H shows an electroluminescence (EL) spectra of PeLEDs with control and solvent-engineered (DMF:NMP=10:1) film.

LEDs were fabricated based on these perovskite films with a device structure of indium tin oxide (ITO) (120 nm)/ZnO-PEIE (30 nm)/perovskite/TFB (50 nm)/MoOₓ (10 nm)/Au (60 nm) as shown in FIG. 1B. As observed from the cross-sectional SEM shown in FIG. 1G, the TFB layer that covers perovskite grains does not make direct contact with the underlying ZnO/PEIE layer even in the presence of a discontinuous perovskite film. This implies that any potential shunt path resulting from structural features is effectively suppressed. The performance of PeLEDs with varying solvent mixing ratio was compared in FIGS. 1C and 1D. Devices with the optimum solvent mixing ratio of DMF:NMP=10:1 produced a maximum radiance of 787 W sr⁻¹ m⁻² and a maximum EQE of 25.6% at 798 nm, which are significantly higher than those of the control device (radiancemax: 655 W sr⁻¹ m⁻², EQEₘₐₓ: 18.4%, peak electroluminescence, EL: 795 nm). The EQE reached the peak value of 25.6% at a high current density of 278 mA cm⁻² and remained over 15% even at 1000 mA cm⁻², demonstrating substantial superiority compared to the state-of-the-art NIR PeLEDs (Table 1). For other devices with mixed solvent ratios of 14:1 and 2:1, maximum EQEs were measured to be 23.3% and 19.1%, respectively.

Tailoring 2D/3D Heterostructures with TeFBTT

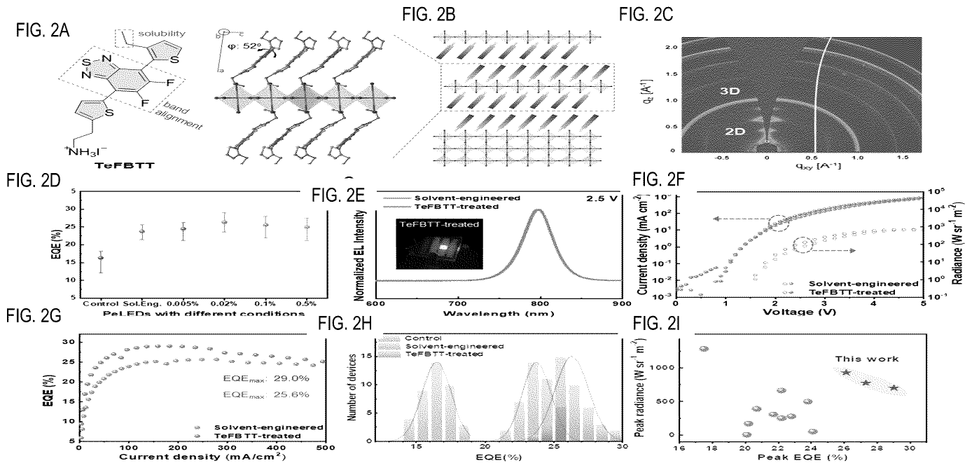

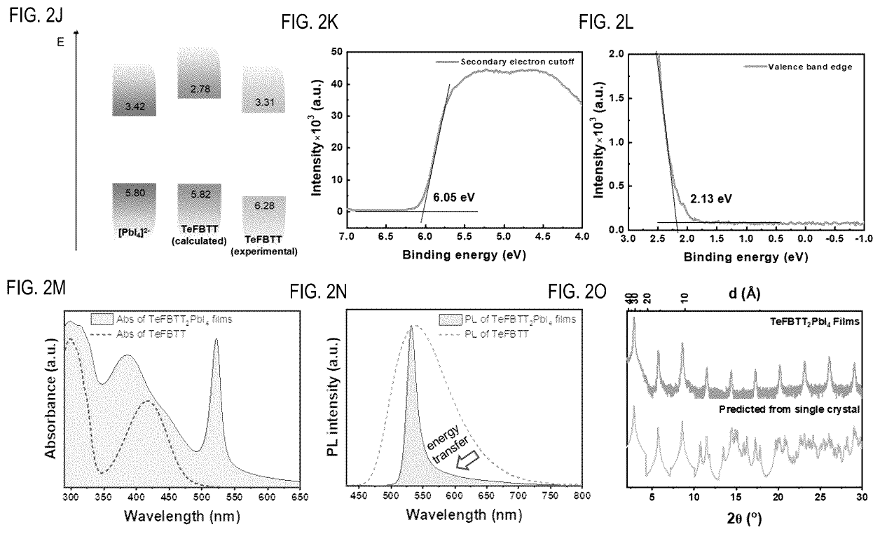

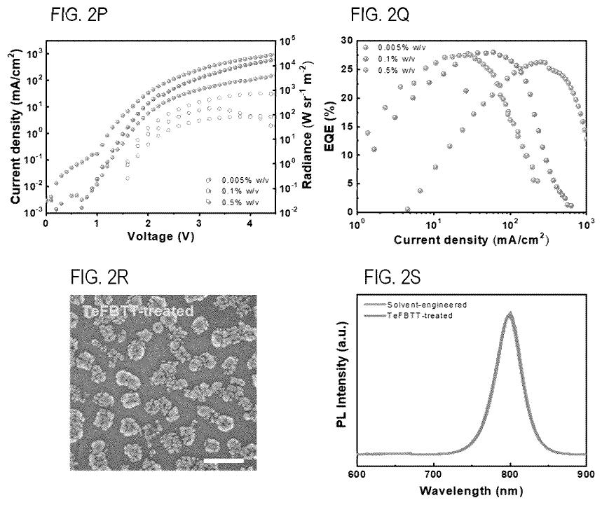

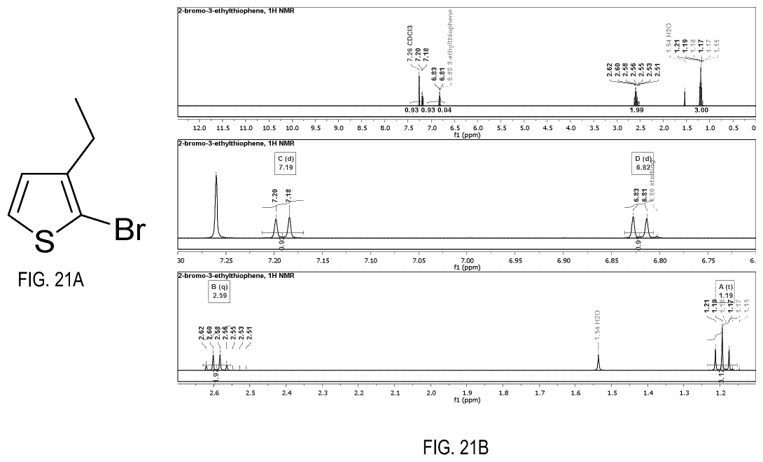

To further boost the device performance, a small-bandgap organic cation, TeFBTT, was designed capable of forming layered 2D perovskites with a properly tailored Type I band alignment that ensures efficient energy transfer to inorganic motifs. FIGS. 2A-2O show aspects of TeFBTT in which FIG. 2A shows the chemical structure of TeFBTT and single crystal structure of (TeFBTT)₂PbI₄, FIG. 2B shows a schematic representation of the TeFBTT-incorporated 2D/3D perovskite heterostructure, FIG. 2C shows a grazing incidence wide angle X-ray scattering (GIWAXS) pattern of a perovskite film with TeFBTT post-treatment, FIG. 2D shows an EQEₘₐₓ of PeLEDs with different conditions (as shown, while the optimum post-treatment concentration is about 0.02%, reasonable concentrations range from about 0.05 to about 0.5%), FIG. 2E shows a EL spectra and light emission camera image, FIG. 2F shows J-V-R curves, FIG. 2G shows EQE characteristics of PeLEDs with solvent-engineered and TeFBTT-treated perovskite films, FIG. 2H shows histograms depicting EQEₘₐₓ of PeLEDs, FIG. 21 shows EQEₘₐₓ based on the data presented in Table 1, FIG. 2J shows an energy band diagram of [PbI₄]²⁻ and TeFBTT with calculated and experimental values. [PbI₄]²⁻ values were sourced from a previous study, FIG. 2K shows secondary electron cutoff, FIG. 2L shows valence band edge spectra of TeFBTT, FIG. 2M shows absorption spectra, FIG. 2N shows PL spectra of (TeFBTT)₂PbI₄ and TeFBTT, and FIG. 2O shows experimental and calculated x-ray diffraction (XRD) spectra of (TeFBTT)₂PbI₄, FIG. 2P shows J-V-R curves of PeLEDs with varying TeFBTT concentrations, FIG. 2Q shows the EQE of PeLEDs with varying TeFBTT concentrations, FIG. 2R shows a SEM image of perovskite films with optimized TeFBTT concentration (0.02% w/v), FIG. 2S shows PL spectra of perovskite films with solvent-engineered and TeFBTT-treated conditions.

TABLE 1
Performance summary of reported NIR PeLEDs.

| | | Peak | | | |
|---|---|---|---|---|---|
| EL | Peak | radiance | | | |
| peak | EQE | (W sr⁻¹ | | | Reference |
| (nm) | (%) | m⁻²) | Device structure | Year | number |
| 799 | 29.0 | 701 | ITO/ZnO/PEIE/FAPbI₃-5AVA- | 2023 | This work |
| | 27.3 | 774 | TeFBTT/TFB/MoOₓ/Au | | |
| | 26.1 | 929 | | | |
| 800 | 23.8 | 497 | ITO/ZnO/PEIE/FAPbI₃-MSPE/ | 2023 | 1 |
| | 22.2 | 663 | poly-TPD/MoOₓ/Au | | |
| 804 | 24.1 | 51.8 | ITO/ZnO/PEIE/CdAc₂-FAPbI₃- | 2022 | 2 |
| | | | 5AVA/TFB/MoOₓ/Au | | |
| 800 | 22.8 | 278.9 | ITO/ZnO/PEIE/FAPbI₃-SFB10/ | 2022 | 3 |
| | | | TFB/MoOₓ/Au | | |
| 800 | 22.2 | ~250 | ITO/ZnO/PEIE/FAPbI₃-AEAA/ | 2021 | 4 |
| | | | TFB/MoOₓ/Au | | |
| 789 | 17.5 | 1282.8 | ITO/ZnO/PEIE/ | 2021 | 5 |
| | | | PPAI-FA_{0.83}Cs_{0.17}PbI₃/TFB/MoOₓ/Au | | |
| 799 | 20.2 | 170 | ITO/ZnO/PEIE/FAPbI₃-5AVA/ | 2020 | 6 |
| | | | poly-TPD/MoOₓ/Au | | |
| 800 | 21.7 | 308 | ITO/ZnO/PEIE/FAPbI₃- | 2019 | 7 |
| | | | ODEA/TFB/MoOₓ/Au | | |
| 803 | 20.7 | 390 | ITO/ZnO/PEIE/FAPbI₃-5AVA/ | 2018 | 8 |
| | | | TFB/MoOₓ/Au | | |
| 795 | 20.1 | ~5 | ITO/MZO/PEIE/(NMA)₂(FA)Pb₂I₇:poly- | 2018 | 9 |
| | | | HEMA/TFB:PFO/MoOₓ/Au | | |

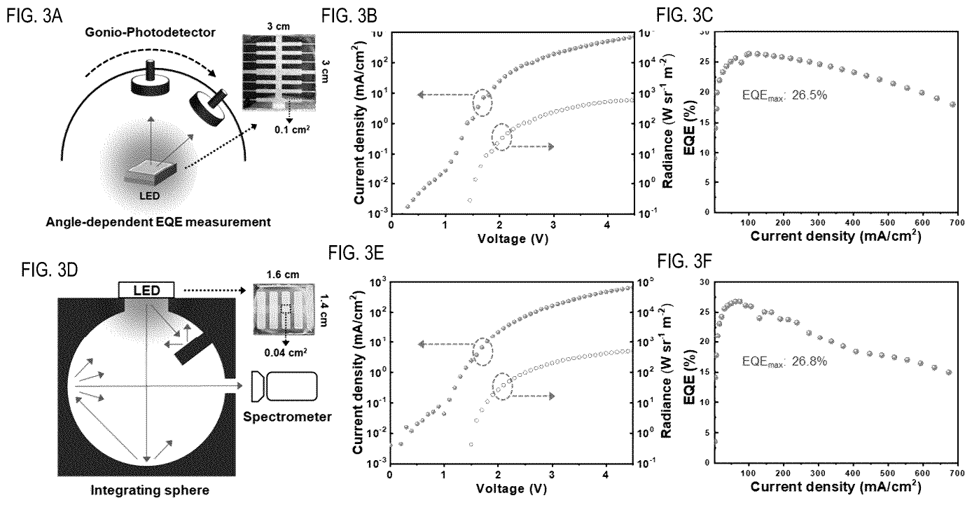

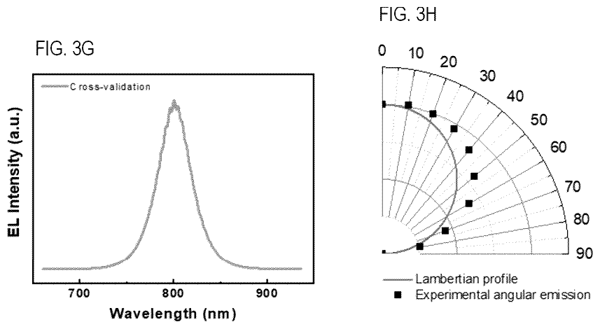

LEDs were fabricated based on these perovskite films with a device structure of indium tin oxide (ITO) (120 nm)/ZnO-PEIE (30 nm)/perovskite/TFB (50 nm)/MoOₓ (10 nm)/Au (60 nm) as shown in FIG. 1B. As observed from the cross-sectional SEM shown in FIG. 1G, the TFB layer that covers perovskite grains does not make direct contact with the underlying ZnO/PEIE layer even in the presence of a discontinuous perovskite film. This implies that any potential shunt path resulting from structural features is effectively suppressed. The performance of PeLEDs with varying solvent mixing ratio was compared in FIGS. 1C and 1D. Devices with the optimum solvent mixing ratio of DMF:NMP=10:1 produced a maximum radiance of 787 W sr⁻¹ m⁻² and a maximum EQE of 25.6% at 798 nm, which are significantly higher than those of the control device (radiancemax: 655 W sr⁻¹ m⁻², EQEₘₐₓ: 18.4%, peak electroluminescence, EL: 795 nm). The EQE reached the peak value of 25.6% at a high current density of 278 mA cm⁻² and remained over 15% even at 1000 mA cm⁻², demonstrating substantial superiority compared to the state-of-the-art NIR PeLEDs (Table 1). For other devices with mixed solvent ratios of 14:1 and 2:1, maximum EQEs were measured to be 23.3% and 19.1%, respectively. FIGS. 3A-3H show cross-validation of PeLEDs in which FIG. 3A shows a schematic representation for angle-dependent EQE measurement in a cross-validation institution, along with a camera image of the tested device, FIG. 3B shows J-V-R curves, FIG. 3C shows EQE characteristics of the device for the cross-validation, FIG. 3D shows a schematic representation of the integrating sphere in our measurement system, accompanied by a camera image of the tested device, FIG. 3E shows J-V-R curves of the device, FIG. 3F shows EQE characteristics of the device, FIG. 3G shows EL spectrum, and FIG. 3H shows ideal Lambertian profile with experimental angular emission data of the cross-validated PeLED. The broader emission profile observed in the experimental angular emission, compared to ideal Lambertian profile, is presumably due to the enhanced light outcoupling effect by island-type perovskite crystal structures.

The chemical structure of TeFBTT and the single crystal structure of the resultant 2D perovskite are illustrated in FIG. 2A. In detail, TeFBTT features a fluorinated benzothiadiazole (FBT) core with deep highest occupied and lowest unoccupied molecular orbitals (HOMO and LUMO) to ensure close alignment with the valence and conduction band of the inorganic octahedral sheet, respectively, as predicted from density functional theory (DFT) and further supported by experiments (whose results are shown in FIGS. 2J-2M). To prevent self-aggregation of organic building blocks and facilitate the formation of layered perovskites, a flexible ethyl side chain was attached to the terminal thiophene to increase solubility and simultaneously twist the backbone from a completely planar structure. The crystal structure of (TeFBTT)₂PbI₄ was solved, revealing well-aligned TeFBTT molecules on top of the inorganic slab with a pronounced torsion angle of 52° between FBT and the terminal thiophene (shown in FIG. 2A). These characteristics culminate in the facile fabrication of (TeFBTT)₂PbI₄ thin films with a well-defined XRD pattern resembling layered perovskites and strong PL emission with a single sharp excitonic peak at 532 nm, confirming the Type I alignment (as shown in FIGS. 2N and 2O).

The strategically designed TeFBTT was used to modify the solvent-engineered perovskite films (DMF:NMP=10:1) and create the heterostructure of 2D/3D perovskites shown in FIG. 2B. GIWAXS patterns of the post-treated FAPbI₃ film shown in FIG. 2C revealed the presence of layered perovskite phases, which verified the spontaneous formation of 2D/3D heterostructures. The impact of the 2D/3D heterostructure on PeLED was investigated with the device structure shown in FIG. 2B. Given that the quantity of 2D perovskites affects the resulting device performance, the concentration of TeFBTT in isopropanol (IPA)/chlorobenzene solution used for post-treatment shown in FIGS. 2D, 2P and 2Q was optimized. The optimal device performance was achieved with a low concentration of 0.02% w/v, where the discontinuous polycrystalline film retained its pre-treatment morphology (shown in FIG. 2R and FIG. 1A). Additionally, both the PL (shown in FIG. 2S) and EL (shown in FIG. 2E) spectra exhibited minimal shifts with and without TeFBTT treatment at the optimized concentration.

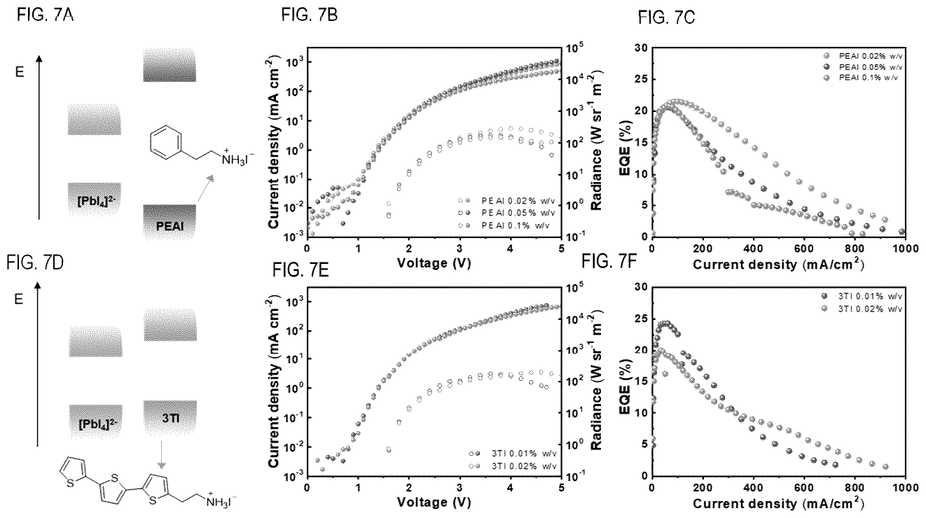

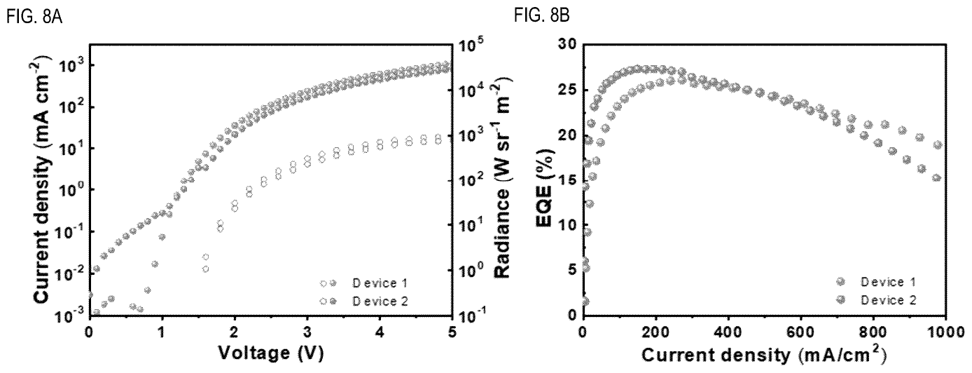

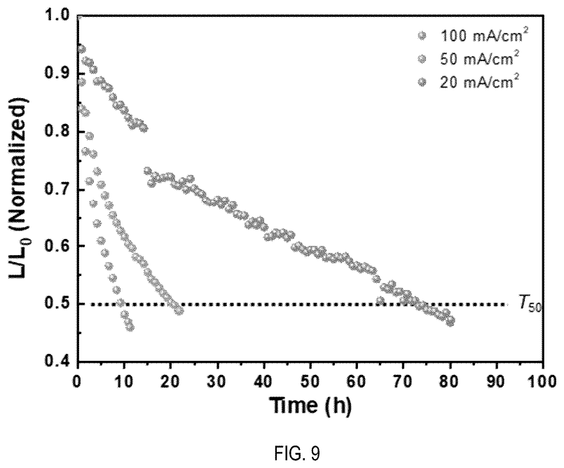

Moreover, the peak EQE was enhanced up to 29.0% at a high current density of 183 mA cm⁻² following the TeFBTT treatment with a maximum radiance of 701 W sr⁻¹ m⁻² as shown in FIGS. 2F and 2G). This is in direct contrast to the poor device performances when wide bandgap organic cations were used for post-modification (FIGS. 7A-7F). Additionally, TeFBTT-treated devices exhibited high reproducibility as shown in FIG. 2H, where the peak EQE histograms displayed mean value of 16.3%, 23.7%, and 26.3%, with standard deviations of 1.3%, 1.0% and 1.2% for control, solvent-engineered, and TeFBTT-treated devices, respectively. This is the highest EQE among the reported NIR PeLEDs and generally higher radiance as shown in FIG. 21 and Table 1. Apart from one device achieving a peak EQE of 29% and a maximum radiance of 701 W sr⁻¹ m⁻², other representative devices exhibited peak EQEs of 27.3% and 26.1%, along with impressive maximum radiances of 774 and 929 W sr⁻¹ m⁻²; respectively (FIGS. 2I, 8A and 8B). The device stability was assessed at different current densities (FIG. 9), revealing T₅₀ values of 73, 21, and 9.3 hours at 20, 50, and 100 mA/cm², respectively.

### Device Cross-Validation

Cross-validating PeLED performances within multiple labs increases the reproducibility and reliability of the results. Furthermore, shipping samples between labs supports the notion of a device being reliable. Given that a widely accepted certification agency has yet to be established, the devices described herein were systematically cross-validated with another group. FIG. 3A illustrates a scheme for angle-dependent EQE measurement based on a gonio-photodetector, which enables the collection of angular distribution data for emitted light from the devices. Notably, larger substrates (3×3 cm) were adopted with an increased active area of 0.1 cm². The device fabrication process was carried out at one location under identical conditions, and then devices were sealed and shipped to a testing location. FIGS. 3B and 3C present the characteristics of the fabricated LEDs as measured at the testing location. The J-V curve exhibited similarity (see FIG. 2F), and the radiance was measured to be 592 W sr⁻¹ m⁻², falling within a reasonable radiance range. The peak EQE was recorded as 26.5%, exceeding the average EQE from an original device distribution, thereby affirming the accuracy of previous measurements.

Device performance may exhibit slight variations from batch to batch, despite stringent fabrication conditions being maintained each time. Consequently, while the batch of devices were prepared for cross-validation, a device under precisely the same conditions was fabricated in parallel to conduct a second validation. The device (1.4 cm×1.6 cm, active area: 0.04 cm²) was assessed using an integrating sphere shown in FIG. 3D and its characteristics are outlined in FIGS. 3E and 3F. The J-V-R trends were nearly identical in operational range, turn-on voltage, and curve shape between the two cross-validation methods. The peak radiance and peak EQE were measured at 500 W sr⁻¹ cm⁻² and 26.8%, respectively, closely mirroring those obtained from the cross-validation institution. These results demonstrate that device performance has been accurately assessed and that the device is not only reproducible (even on larger substrates) but also transferable without noticeable degradation for further use.

### Underlying Factors of Superior PeLED Performance

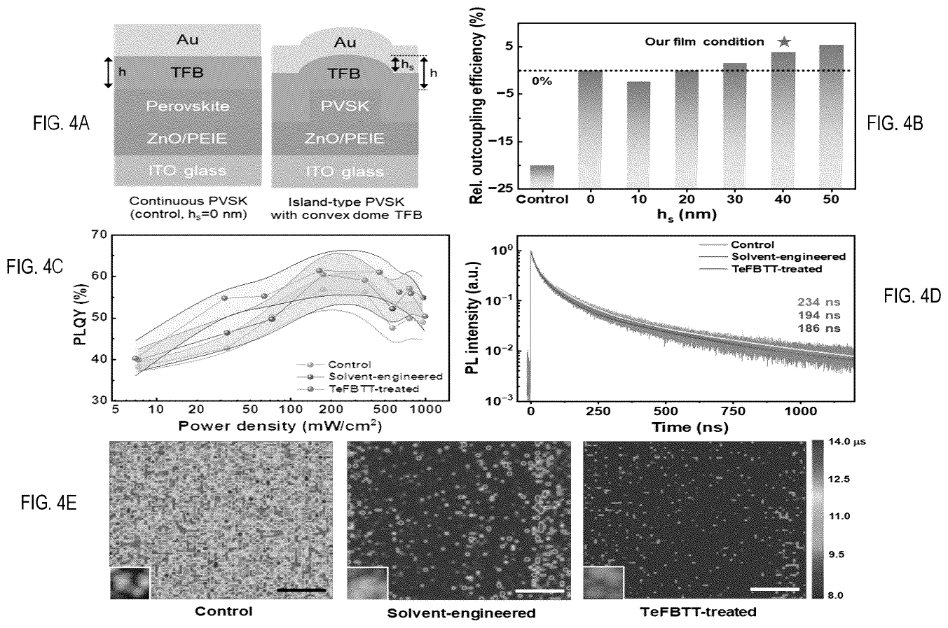

FIGS. 4A-4E show PeLED aspects and performance, in which FIG. 4A shows device structures with single grain cell for outcoupling efficiency simulation, FIG. 4B shows simulated relative outcoupling efficiencies of perovskite films with varying convex height (hₛ), FIG. 4C shows average PL quantum yields (PLQYs) (shadow region: standard deviation), FIG. 4D shows time-resolved PL (TRPL) spectra, and FIG. 4E shows nanoscale charge-carrier recombination lifetime mapping (100 nm×100 nm) and corresponding AFM images (inset) of perovskite films with control, solvent-engineered, and TeFBTT-treated condition (scale bar: 20 nm).

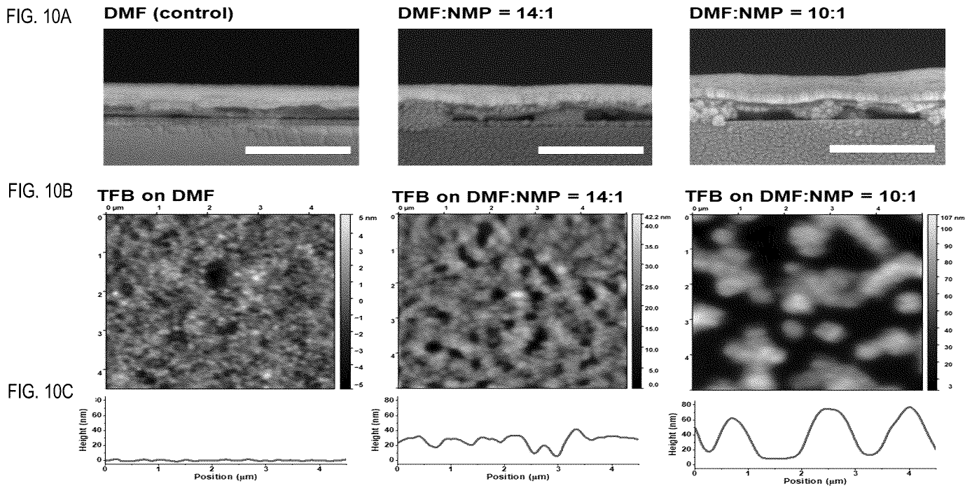

The high performance achieved by our PeLEDs is due to combined effects including morphological factors, suppressed defect formation, and rapid radiative recombination of charge carriers. One advantage of an α-FAPbI₃-based PeLED with discontinuous film morphology lies in outcoupling efficiency. The randomly distributed perovskite crystals can function as isolated light emitters and light scatterers; these discrete grains combined with the sequentially deposited layers and form convex structures especially from the reflective surface of gold, which effectively facilitate the extraction of light that would otherwise be confined in the waveguide modes. The overall “discrete island-convex dome” morphology was further amplified with the addition of NMP, which led to dramatically increased average grain size and notably reduced packing density as shown in FIG. 1A. Cross-sectional SEM images of devices validated the formation of convex “wavy” patterns from the subsequently deposited layers, which was negligible when only DMF was used but became considerable at the condition of DMF:NMP=10:1 due to notable increase in grain size and reduction in grain density aforementioned (as shown in FIGS. 1A, 1G, and 10A-10C).

Furthermore, the effect of amplified convex dome morphology was evaluated with 3D 3D-FDTD simulations from a representative single-grain cell as shown in FIG. 4A. A gradually increased light outcoupling efficiency was observed upon gradually increasing the convex height (hₛ) on top of the subsequently-fabricated TFB layer, while all models based on discrete perovskite grains significantly outperforms the continuous film-based model by at least 20%. In this way, through solvent-engineering with NMP addition, the grain size and packing density of polycrystalline perovskite film can be tailored to have desired light scattering behaviors, benefitting the efficient extraction of trapped emission.

In addition to morphological enhancement, the mixed solvent of DMF and NMP suppresses the formation of defects through intermediate phase-assisted crystallization. To substantiate this, the PLQYs of the perovskite films were characterized as shown in FIG. 4C. Notably, the solvent-engineered film with optimal mixing ratio consistently demonstrated higher PLQY irrespective of laser power, reaching a maximum value of 62%. This stands in contrast to the control film (53%), providing strong evidence of fewer defects. Furthermore, in the case of the TeFBTT-treated film, the maximum PLQY was further enhanced to 65%. This suggests that the 2D phase obtained by the TeFBTT post-treatment offers further passivation of defects within the 3D phase.

Furthermore, TRPL was performed for each perovskite film as shown in FIG. 4D to determine the dynamics of charge carrier radiative recombination. The average lifetimes (τₐᵥₑ) for control, solvent-engineered, and TeFBTT-treated film were determined to be 234, 194, and 186 ns, respectively (Table 2).

TABLE 2
TRPL results, maximum PLQYs, and charge-carrier recombination rates.

| | | τ₁ | | τ₂ | | τ₃ | τ_{avg} | PLQYₘₐₓ | kᵣ | kₙᵣ |
|---|---|---|---|---|---|---|---|---|---|---|
| | A₁ | (s) | A₂ | (s) | A₃ | (s) | (s) | (%) | (s⁻¹) | (s⁻¹) |
| Control | 0.573 | 19.3 | 0.334 | 91.2 | 0.073 | 443 | 234 | 53% | 2.26 × 10⁶ | 2.01 × 10⁶ |
| Solvent- | 0.522 | 13.9 | 0.354 | 66.1 | 0.086 | 341 | 194 | 62% | 3.20 × 10⁶ | 1.96 × 10⁶ |
| engineered | | | | | | | | | | |
| TeFBTT- | 0.428 | 10.5 | 0.408 | 55.4 | 0.119 | 294 | 186 | 65% | 3.49 × 10⁶ | 1.88 × 10⁶ |
| treated | | | | | | | | | | |

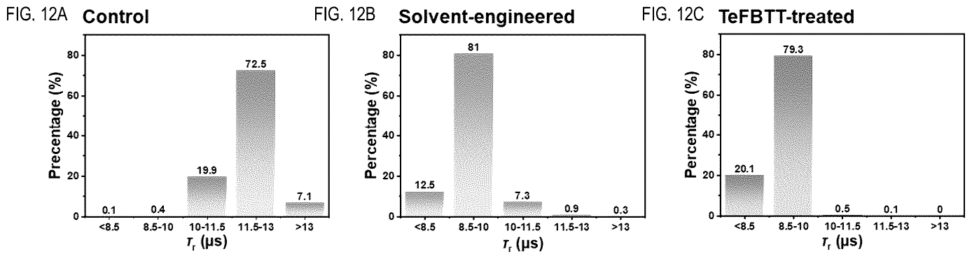

Calculations were determined for the carrier recombination rate, as detailed in Table 2, with control films (kᵣ: 2.26×10⁶ s⁻¹, kₙᵣ: 2.01×10⁶ s⁻¹), solvent-engineered (kᵣ: 3.20×10⁶ s⁻¹, kₙᵣ: 1.96×10⁶ s⁻¹), and TeFBTT-treated (kᵣ: 3.49×10⁶ s⁻¹, kₙᵣ: 1.88×10⁶ s⁻¹). There are nearly three and two-fold enhancements in radiative recombination rate for TeFBTT-treated and solvent-engineered films compared to the control film, respectively. This trend is consistent with the enhancement in device performance, as faster radiative recombination is generally preferred in LED operation. Nanoscale charge-carrier recombination lifetime mapping was performed on each crystal grain, as shown in FIG. 4E and FIGS. 12A-12C, to determine carrier dynamics. The average charge-carrier recombination lifetimes for control, solvent-engineered, and TeFBTT-treated films were measured to be 12.0, 9.2, and 8.8 μs, respectively, consistent with the trends observed in the TRPL measurements. The mapping images reveal that the solvent-engineered film exhibits a marginally reduced recombination rate at its periphery. Conversely, in the case of TeFBTT-treated film, the recombination rate displays a more uniform distribution across the entire region, indicating a uniform organic cation coating on the surface of perovskites, yielding a higher quality film.

Accordingly, solvent engineering and 2D/3D heterostructure have been used to enhance the performance of NIR PeLEDs. Through a systematic exploration of solvent mixtures, an amplified version of discontinuous island-convex dome morphology was achieved. Notably, the discrete grains with convex dome structure by the sequentially deposited TFB/Au layer led to the enhanced outcoupling efficiency, coupled with a reduction in defects and fast radiative recombination of charge carriers. This resulted in a significant enhancement of device performance, yielding a maximum radiance of 787 W sr⁻¹ m⁻² and a peak EQE of 25.6%. Further advancements were made by introducing TeFBTT organic cation to form a 2D/3D perovskite heterostructure. This post-treatment strategy led to an even higher peak EQE of 29.0%. The enhancement in peak EQE is attributed to the combined effects of passivated defects, rapid radiative recombination, and balanced charge carrier recombination.

### Methods

### Materials

The perovskite precursor solutions were prepared using FAI (99.99%, Greatcell Solar Materials), PbI₂ (99.99%, TCI America), and 5AVA (97%, Sigma Aldrich) with a molar ratio of 2.5:1:0.7, which were dissolved in mixed solvents of DMF and NMP (Anhydrous, Sigma Aldrich) with different ratios at 60° C. for 2 h with stirring (For device stability tests, 5AVA ratio was increased to 1.0). The total precursor concentrations of the resulting solutions were maintained at 10 wt %. Note, the exact chemistry involves the self-dehydration of 5AVA to form a lactam product 2-piperidone in solution upon heating, which competes with the reaction between 5AVA and FAI. ZnO nanocrystals (NCs) were synthesized. PEIE (80% ethoxylated solution, Sigma Aldrich), TFB (Sigma Aldrich), and MoOₓ (99.97%, Sigma Aldrich) were used. Regarding perovskite single crystal growth, PbI₂ (99.999% trace metals basis, perovskite grade, #900168), hydroiodic acid (HI, 57 wt. % in H₂O), and hypophosphorous acid (H₃PO₂, 50 wt. % in H₂O) from Sigma Aldrich were used. Regarding organic synthesis, deuterated dimethyl sulfoxide (DMSO-d6) and deuterated chloroform (CDCl₃) from Sigma Aldrich were used. Reagents and precursors used in organic synthesis were used from Sigma Aldrich or Fisher Scientific.

### Synthesis of TeFBTT

The complete synthetic scheme is included in Scheme 2. tert-butyl(2-(5-(tributylstannyl)thiophen-2-yl)ethyl)carbamate was synthesized. 2-bromo-3-ethylthiophene: a flame-dried round-bottom flask was equipped with a magnetic stir bar and a dropping funnel. A solution of 3-ethylthiophene (1.1219 g, 10 mmol, 1 equiv.) in anhydrous acetonitrile (10 mL, 1 M) was added to the flask. A solution of N-bromo-succinimide (1.958 g, 11 mmol, 1.1 eq) in anhydrous acetonitrile (22 mL, 0.5 M) was added to the dropping funnel. The entire system was sealed and protected with argon, after which the solution containing 3-ethylthiophene was heated to 40° C. With vigorous stirring, the NBS solution was slowly added to the flask with a dropping speed of 1 min/drop (syringe pump is recommended for future study). The procedure was designed to maintain a low NBS concentration at any given time and thus, prevent the di-substitution of 3-ethylthiophene with bromine. After the addition of NBS, stirring was continued for another hour before the solvent is evaporated with a rotary evaporator. The residue is dissolved in EA, washed twice with 2M aq. NaOH followed by brine, dried over MgSO₄, filtered and concentrated. The product (58.4% yield) was used without further purification. Less than 5 mol % of the starting material, 3-ethylthiophene was detected from the product through NMR, while no di-substituted product was detected. ¹H NMR (400 MHZ, CDCl₃) δ 7.19 (d, J=5.6 Hz, 1H), 6.82 (d, J=5.6 Hz, 1H), 2.59 (q, J=7.6 Hz, 2H), 1.19 (t, J=7.6 Hz, 3H).

tributyl(3-ethylthiophen-2-yl) stannane: to a solution of 2-bromo-3-ethylthiophene (1.1161 g, 5.8407 mmol, 1 equiv.) in ether (11.68 mL, 2 mL/mmol) at −78° C. was add n-BuLi (2.5 M in hexane, 2.57 mL, 6.4248 mmol, 1.1 equiv.) slowly dropwise. The solution gradually turned yellow, and the reaction was kept stirring at −78° C. for 80 mins. Then, tributylstannyl chloride (1.74 mL, 6.4248 mmol, 1.1 equiv.) was added at the same temperature. The mixture immediately turned colorless and was allowed to warm to room temperature naturally and kept stirring for 12 hours. After washing with water, the organic phase was collected, and the aqueous phase was washed with ether. The combined organic phases were washed with brine, dried, and the solvent was removed through rotary evaporation to provide the desired product (2.9663 g) as a clear pale-yellow oil which was used without further purification. The product is assumed to be 79% pure by assume a 100% yield.

BrFBTT-Boc, tert-butyl(2-(5-(7-bromo-5,6-difluorobenzo[c][1,2,5]thiadiazol 4-yl)thiophen-2-yl)ethyl)carbamate: tert-butyl (2-(5-(trimethylstannyl)thiophen-2-yl)ethyl)carbamate (1.951 g, 5 mmol), tris(dibenzylideneacetone)dipalladium(0) (37 mg, 2 mol %), tri(o-tolyl)phosphine (49 mg, 8 mol %), and 4,7-dibromo-5,6-difluorobenzo[c][1,2,5]thiadiazole (3.299 g, 10 mmol) were mixed in a 100 mL flame-dried round bottom flask. After argon protection, anhydrous toluene (50 mL, 0.1 M) was added via syringe. The mixture was refluxed for 12 hours at 105° C. After cooling to room temperature, water was added, and the mixture was extracted with dichloromethane (DCM). The organic layers were combined, washed with brine and dried over sodium sulfate. The solids were removed by filtration, solvents were removed under vacuum and the residue was purified through silica column chromatography (hexane:ethylacetate). Desired mono-substituted product was isolated with 28.8% yield. ¹H NMR. (400 MHz, CDCl₃) δ 8.11 (d, J=3.8 Hz, 1H), 7.00 (d, J=3.9 Hz, 1H), 3.48 (d, J=4.4 Hz, 2H), 3.12 (t, J=6.7 Hz, 2H), 1.45 (s, 9H).

TeFBTT-Boc, tert-butyl (2-(5-(7-(3-ethylthiophen-2-yl)-5,6-difluorobenzo[c][1,2,5]thiadiazol-4-yl)thiophen-2-yl)ethyl)carbamate: tributyl(3-ethylthiophen-2-yl) stannane (79% purity, 811 mg, ca. 1.6 mmol, 2 eq.), tris(dibenzylideneacetone)dipalladium(0) (58.8 mg, ca. 4 mol %), tri(o-tolyl)phosphine (79.3 mg, ca. 16 mol %), and BrFBTT-Boc (382.3 mg, ca. 0.8 mmol) were mixed in a 50 mL flame-dried round bottom flask. After protection with argon, anhydrous toluene (16 mL, 0.1 M) was added via syringe. The mixture was refluxed overnight at 105° C. Purification was proceeded similar to BrFBTT-Boc. Desired product was isolated with 100% yield. 1H NMR (400 MHz, CDCl₃) δ 8.16 (d, J=3.1 Hz, 1H), 7.55 (d, J=5.1 Hz, 1H), 7.15 (d, J=5.3 Hz, 1H), 7.02 (d, J=3.3 Hz, 1H), 4.74 (s, 1H), 3.53-3.46 (m, 2H), 3.13 (t, J=6.7 Hz, 2H), 2.54 (q, J=6.8 Hz, 2H), 1.46 (s, 9H), 1.20 (t, J=7.7 Hz, 3H).

TeFBTT, iodide salt, 2-(5-(7-(3-ethylthiophen-2-yl)-5,6-difluorobenzo[c][1,2,5]thia-diazol-4-yl)thiophen-2-yl)ethan-1-aminium iodide: TeFBTT-Boc (391.9 mg, 0.7720 mmol, 1 equiv.) was dissolved in anhydrous ethanol (15.44 mL, 20 mL/mmol) (a few drops of dichloromethane were added to aid solubility), and 57 wt % aqueous HI solution (346.49 mg, 2.0 equiv.) was then added to cleave the boc protecting group and in-situ from the ammonium iodides of the ligands. After protection with argon, the mixture was refluxed at 70° C. for 3 hours and left stirring overnight. After reaction, the solvent was mostly removed with rotary evaporation at 40° C. Then the resulted crude product was reprecipitated at least thrice using ethanol and ether. Product was a bright yellow powder (80.9% yield). ¹H NMR (500 MHz, DMSO-d6) δ 8.15 (d, J=3.8 Hz, 1H), 7.82 (d, J=5.2 Hz, 1H), 7.79 (s, 3H), 7.23 (d, J=5.2 Hz, 2H), 3.21 (q, J=3.9 Hz, 4H), 2.48 (t, 2H), 1.13 (t, J=7.6 Hz, 3H). ¹⁹F NMR (470 MHz, DMSO-d6, uncalibrated) δ −128.41 (d, J=19.9 Hz), −129.78 (d, J=19.1 Hz). ¹³C NMR (126 MHz, DMSO-d6) δ 150.47 (d, J=7.7 Hz), 150.47 (dd, J=209.7, 19.2 Hz), 148.44 (dd, J_{CF}=214.2, 19.2 Hz), 147.89 (d, J_{CF}=9.0 Hz), 145.00, 143.51 (d, J_{CF}=6.2 Hz), 131.59 (d, J_{CF}=7.9 Hz), 129.26, 128.47, 128.42, 126.86, 122.68, 112.50 (d, J_{CF}=12.4 Hz), 111.02 (d, J_{CF}=16.4 Hz), 27.43 (s, 2C), 22.15, 14.59.

### Nuclear Magnetic Resonance (NMR)

NMR spectra were acquired at room temperature with a Bruker Avance III HD 400 MHz spectrometer equipped with a 2-channel Nanobay console and a 5 mm BBFO Z-gradient SmartProbe, or Bruker NEO 500 MHz equipped with prodigy liquid-nitrogen cooled cryoprobe with BBFO configuration. NMR spectra were analyzed with Mestrenova. ¹H peaks were calibrated with that of CHCl₃ (δ 7.26) in CDCl₃ or DMSO (δ 2.5) in DMSO-d6. ¹³C peaks were calibrated with that of DMSO (δ 39.2) in DMSO-d6. ¹⁹F peaks were uncalibrated. Processed NMR spectra are included in the figures.

### Perovskite Single Crystal Growth

Bulk iodide perovskite single crystals were obtained through slow-cooling a solution composed of PbI₂ (10 mg) and the organic ammonium salt, TeFBTT (1 mg) in HI (200 μL), H₃PO₂ (100 μL), and ethanol (400 μL) as solvents. Ethanol increases the solubility of conjugated organic ammonium salts in aqueous condition reported in our previous study. In detail, the precursors and solvents were mixed in a 4 mL scintillation vial. After being tightly capped, the sample vial was heated carefully in a boiling water bath to until materials were completely dissolved, and the solution was clear. Sonication was occasionally used to assist the dissolution of materials, but magnetic stirring was avoided. Then, the vial was transferred to and sealed in a Dewar flask containing boiling water, which was then stored at ambient conditions to allow slow-cooling for 72-96 hours until the water bath reached room temperature. The crystal was stored in solution until being removed for structure determination and face indexing.

### Single Crystal X-Ray Diffraction (SC-XRD)

Single crystals of the investigated compounds were coated with a trace of Fomblin oil and were transferred to the goniometer head of a Bruker Quest diffractometer. Data for (TeFBTT)₂PbI₄ were collected on an instrument with kappa geometry, a Cu Kα wavelength (λ=1.54178 Å) I-μ-S microsource X-ray tube, a laterally graded multilayer (Goebel) mirror for monochromatization, and a Photon III C14 area detector. The instrument was equipped with an Oxford Cryosystems low temperature device and examination and data collection were performed at 150 K.

Data were collected, reflections were indexed and processed, and the files scaled and corrected for absorption using APEX4 and SADABS or TWINABS. The space groups were assigned using XPREP within the SHELXTL suite of programs and solved by dual methods using ShelXT and refined by full matrix least squares against F2 with all reflections using Shelx12018 or Shelx12019, and the graphical interface Shelxle. Where not specified otherwise (Table 3 and associated text), H atoms were handled as follows: H atoms attached to carbon and nitrogen atoms as well as hydroxyl hydrogens were positioned geometrically and constrained to ride on their parent atoms. C—H bond distances were constrained to 0.95 Å for aromatic and alkene C—H moieties, and to 0.99 and 0.98 Å for aliphatic CH₂ and CH₃ moieties, respectively. Methyl CH₃, ammonium NH₃⁺ and hydroxyl H atoms were allowed to rotate but not to tip to best fit the experimental electron density. Water H atom positions were refined, and O—H distances were restrained to 0.84(2) Å. Where necessary, water H . . . H distances were restrained to 1.36(2) Å, and H atom positions were further restrained based on hydrogen bonding considerations. Uiso(H) values were set to a multiple of Ueq(C) with 1.5 for CH₃, NH₃⁺ and OH, and 1.2 for C—H and CH₂ units, respectively.

TABLE 3
Crystal data and structure refinement for (TeFBTT)₂PbI₄.

| CCDC# | 2305444 | |
|---|---|---|
| Moiety formula | (C₁₈H₁₆F₂N₃S₃)₂PbI₄ | |
| Empirical formula | C₃₆H₃₂F₄I₄N₆PbS₆ | |
| Formula weight | 1531.82 | |
| Temperature [K] | 150 | (2) |
| Crystal system | monoclinic | |
| Space group (number) | P2₁/c (14) | |
| a [A] | 30.918 | (11) |
| b [Å] | 8.539 | (2) |
| c [Å] | 8.892 | (2) |
| α [°] | 90 | |
| β [°] | 95.659 | (19) |
| γ [°] | 90 | |
| Volume [Å³] | 2336.1 | (11) |

| | |
|---|---|
| Z | 2 |
| ρ_{calc} [gcm⁻³] | 2.178 |
| μ [mm⁻¹] | 30.710 |
| F(000) | 1432 |
| Crystal size [mm³] | 0.005 × 0.100 × 0.120 |
| Crystal colour | orange |
| Crystal shape | plate |
| Radiation | CuKₐ (λ = 1.54178 Å) |
| 2θ range [°] | 5.74 to 140.07 (0.82 Å) |
| Index ranges | −38 ≤ h ≤ 37 |
| | −10 ≤ k ≤ 10 |
| | −10 ≤ l ≤ 10 |
| Reflections collected | 16238 |
| Independent reflections | 16238 |
| | Rᵢₙₜ = 0.0920 |
| | R_{sigma} = 0.1444 |
| Completeness to θ = 67.679° | 99.2% |
| Data/Restraints/Parameters | 16238/979/474 |
| Goodness-of-fit on F² | 1.045 |
| Final R indexes [I ≥ 2σ(I)] | R₁ = 0.0952 |
| | wR₂ = 0.2377 |
| Final R indexes [all data] | R₁ = 0.1511 |
| | wR₂ = 0.2830 |
| Largest peak/hole [eÅ⁻³] | 3.12/−2.98 |

Additional data collection and refinement details, including description of disorder (where present) can be found in Table 3. Complete crystallographic data, in CIF format, have been deposited with the Cambridge Crystallographic Data Centre (CCDC), with the deposition number 2305444. CCDC contains the crystallographic data for this application. The program Mercury was used for crystal structure illustration in this article.

### Device Fabrication

The ITO-coated glass substrates were cleaned consecutively in detergent, de-ionized (DI) water, acetone, and IPA under sonication for 15 min each. The cleaned ITO substrates were treated with UV-ozone for 20 min. Next, ZnO nanocones (NCs) were spin-coated at 2,000 rpm for 30 s, followed by annealing at 150° C. for 10 min. Then, PEIE layer (0.04 wt % dissolved in IPA) was spin-coated at 5,000 rpm, followed by annealing at 100° C. for 10 min. Subsequently, the substrates were transferred into a N₂-filled glove box. The prepared perovskite precursors were filtered through a 0.45 μm pore size polytetrafluoroethylene (PTFE) syringe filter and spin-coated onto the ZnO/PEIE-coated substrates at 3,000 rpm for 1 min, followed by annealing at 100° C. for 16 min. In the case of TeFBTT post-treated samples, 50 μL of TeFBTT solution (dissolved in a mixed solvent of IPA and chlorobenzene with a ratio of 1:3) was dynamically spin-coated at 3,000 rpm for 30 s. Next, TFB (12 mg/mL in toluene) layer was spin-coated at 4,000 rpm. Finally, MoOₓ (10 nm) and Au (60 nm) top electrode were sequentially deposited by thermal evaporation under high vacuum (<2×10⁻⁶ mbar). The active area of the devices was defined to be 0.04 cm² by the overlapping area of the ITO and Au electrodes.

### Device Characterizations

All LED devices were characterized at room temperature in a N₂-filled glove box without encapsulation. The current density versus voltage characteristics were measured using a Keithley 2450 source-measure unit. The luminance characteristics (radiance, EL, EQE, and operational stability) were obtained using a 100 mm PTFE integrating sphere coupled with a spectrometer (Enli Technology, LQ-100X). The whole system is calibrated by a NIST-traceable standard QTH lamp. The operational stabilities of LEDs were measured at constant current densities.

### Device Cross-Validation

LED devices were cross-validated at a testing location, where samples were first sealed in an N₂ atmosphere bag and further sealed in an air-tight shipping tube to reduce O₂ and H₂O exposure. In the testing location, characterization is performed at room temperature in a N₂-filled glove box without encapsulation. A homemade goniometer setup allows angle-dependent emission measurements using a silicon photodiode with a known responsivity curve. J-V measurements are collected using a Keithley 2400 SourceMeter. Emission was characterized by collecting photocurrent in the forward-emitting direction at each voltage step using a Hewlett Packard 4140B pA Meter/DC Voltage Source. The emission spectrum is collected using a StellarNet Epp 2000 spectrometer using a fiberoptic cable. Emission angular dependence was collected by running 2 typical high-performing LEDs for each 3×3 cm substrate at a constant current of 0.6 mA (using the same Keithley SourceMeter) while photocurrent is collected in 10° steps between 0° and 80° from the normal, with diode position controlled using a ThorLabs TDC001 servo controller. Results from the two devices are compared against each other and against a Lambertian profile to verify reasonable, repeatable results. With this trend, the forward emission photocurrent (collected at 0°) is used to recreate the expected photocurrent profile of the entire half-sphere of emission by assuming axis-symmetry of the LED, allowing integration over this region to calculate total photons emitted (spectrum is found to be independent of emission angle). EQE, radiance, luminance, and power and current efficiency are then derivable from the collected data for every voltage step after turn-on.

### Morphological Characterizations

The SEM images were taken using Hitachi S-4800 field emission SEM. AFM was conducted with an Asylum Cypher ES AFM. AFM topographic images were used to extract the average grain height (H) of perovskites and the convex height (hₛ) on top of the subsequently fabricated TFB layers. SEM topographic images were used to extract the average grain size and packing density (α) of the grains.

### PXRD Characterizations

PXRD spectra were obtained by Rigaku Smart Lab using Cu Kα source.

### Steady State Optical Measurements

UV-Vis absorption spectra were recorded on an Agilent UV-Vis-NIR Cary-5000 spectrometer in transmission mode. The steady state PL spectra were obtained with an Olympus microscope system (BX53) integrated with an X-CITE 120Q UV lamp. The filter cube in the microscope contains a 330-385 nm bandpass filter for excitation and a dichroic mirror with 420 nm cutoff wavelength for light splitting. PL spectra were collected with a SpectraPro HRS-300 spectrometer. PLQY was measured with a home-designed system, which consists of a continuous wave OBIS 375 nm laser excitation source, an integrating sphere, optical fiber, and the same spectrometer mentioned above. Perovskite films used for PLQY measurements were fabricated on ITO/ZnO/PEIE with the same method described in device fabrication. An optically-inert layer of isotactic poly(methyl methacrylate) (>80% isotactic, Sigma Aldrich) was spin-coated (1 wt % in anhydrous toluene, 4,000 rpm, 30 s) onto the perovskite layer to mimic TFB as well as providing mild protection against oxygen and moisture. This additional layer of polymer is used to achieve considerable PLQY from the perovskites. PLQY measurements were conducted immediately after the film fabrication. PLQY from more than three films were measured at each power. A minimum of 30 spectra were collected and averaged from each film at various locations by turning the mount stage to remove spatial variation. The PLQY values from each film were then averaged to obtain the average PLQY at each power, which was used for obtaining the power dependent PLQY curves in FIG. 4C. The PLQY value of the best performing film was chosen as the maximum value.

### Time-Resolved Photoluminescence (TRPL) Measurements

TRPL spectra were measured by a home-built PL microscope. A femtosecond pulsed laser (Light conversion, Orpheus high power optical parametric amplifier, ORPHEUS-HP; Carbide femtosecond laser system, CB3-40 W) with excitation wavelength of 447 nm and 203 kHz repetition rate was used as excitation, focused with 40× objective with numerical aperture (NA) of 0.6. TRPL was measured by a single-photon avalanche diode and a single-photon counting module (PicoQuant) with the time resolution of 64 ps. TRPL traces were fitted with triexponential decay convoluted with instrumental response function as below:

$$I ( t ) = conv ( exp ( - \frac{{t}^{2}}{{w}^{2}} ) , Θ ( {t}_{0} ) \cdot {\sum }_{n} ( {A}_{n} \cdot exp ( - \frac{t}{{τ}_{n}} ) )$$

Regarding the radiative and nonradiative recombination rates (k_{rad}, k_{nonrad}) of each film, the equation of

$$\frac{1}{{τ}_{ave}} = {k}_{rad} + {k}_{nonrad} and PLQY = \frac{{k}_{rad}}{{k}_{rad} + {k}_{nonrad}} was$$

employed.

Perovskite films used for TRPL measurements were fabricated on ITO/ZnO/PEIE with the same method described in device fabrication. To suppress the degradation from exposure to the air, the substrates were encapsulated using glasses and epoxy resin.

### Nanoscale Charge-Carrier Recombination Rate Mapping

Local transient photovoltage (TPV) decays in contact mode were measured using an Agilent 5500 conductive atomic force microscopy. A platinum/chromium coated silicon conductive tip was ordered from Budget Sensors with a force constant of 0.20 N/m and resonance frequency of 14 kHz. An Agilent MSOX4154A oscilloscope was used to obtain transient TPV data. An MGL-I-532 DPSS green laser pulse (532 nm wavelength) was used as the light source to generate charge carriers. An Agilent N9447A Breakout Box was connected to the oscilloscope to receive the transient signal from the AFM controller. The oscilloscope input impedance of 1.0 MΩ for TPV was used for collecting transient decays. A mono-exponential decay model was used to calculate the charge carrier recombination lifetime (τᵣ):

$$A ( t ) = {A}_{0} {e}^{\frac{- t}{τ}}$$

where A₀ is steady state photovoltage and τ is time constant that represents charge carrier lifetime.

### GIWAXS

GIWAXS spectra were obtained at beamline 7.3.3 at the Advanced Light Source at Lawrence Berkeley National Laboratory using an incident angle of 0.1° and wavelength of 1.24 Å (10 keV energy). The detector used was Pilatus 2M (Dectris, Inc.) and the data were calibrated using silver behenate as a standard through Igor Pro NIKA package. Perovskite films used for GIWAXS measurements were fabricated on ITO/ZnO/PEIE with the same method described in device fabrication.

### UPS Measurements

UPS measurements were performed in a PHI 5600 analysis system with a hemispherical electron energy analyzer equipped with a multichannel plate detector. The spectra were collected with a H Lyman-α photon source (E-LUX 121, photon energy of 10.2 eV) and a 5.85 eV pass energy.

### Optical Simulations

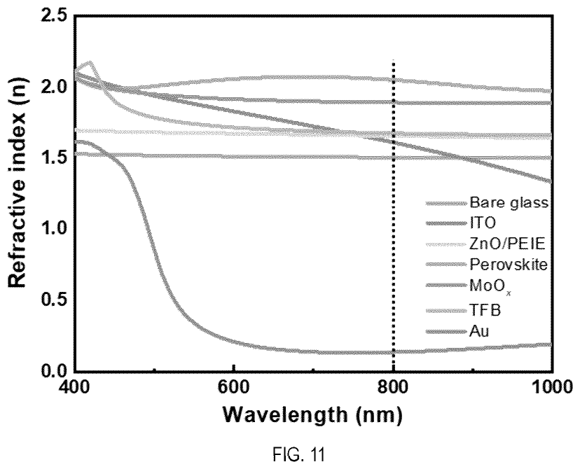

A single cell with active component geometry was used for 3D-FDTD simulations. A mesh size of 2 nm is applied in all three directions in the dipole source region and Δz=1 nm in the convex structures. A perfect match layer (PML) boundary condition is used at the glass substrate and all x,y directions. A metal boundary condition is applied at the gold layer. Multiple simulations with different polarizations were carried out to simulate the incoherent isotropic light source in a 4×4 uniformly distributed dipole source in one perovskite region. Lumerical's far-field analysis group is implemented to calculate the far-field out-coupling power using the near-field power at the glass-ITO interface. The theoretical out-coupling efficiency is then calculated with the division of out-coupling power by the source power obtained inside the dipole power box. 800 nm was chosen as the wavelength of interest. The refractive index of Au, MoOx, TFB, perovskite, ZnO, ITO, and glass were extracted from an ellipsometer (J. A. Woollam V-Vase UV-vis-NIR spectroscopic ellipsometer) measurement (FIG. 11). Note the imaginary part of the refractive index of perovskite is ignored in the simulation.

### Molecular Simulations

Geometry optimizations and excited state calculations for TeFBTT were carried out by means of Density Function Theory (DFT) and Time-Dependent DFT (TDDFT) as implemented in the Gaussian 16 package using the B3LYP functional and def2-TZVP basis set in vacuum. An alkylamine (—CH₂—CH₂—NH₂) was used instead of the alkylammonium tail. In some embodiments, an expensive basis set like def2-TZVP is used to achieve adequate accuracy in DFT and TDDFT calculations when considering the band alignment within perovskites.

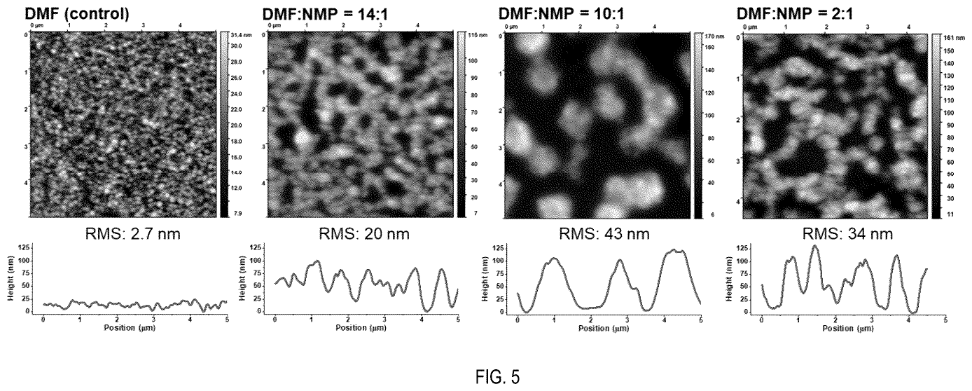

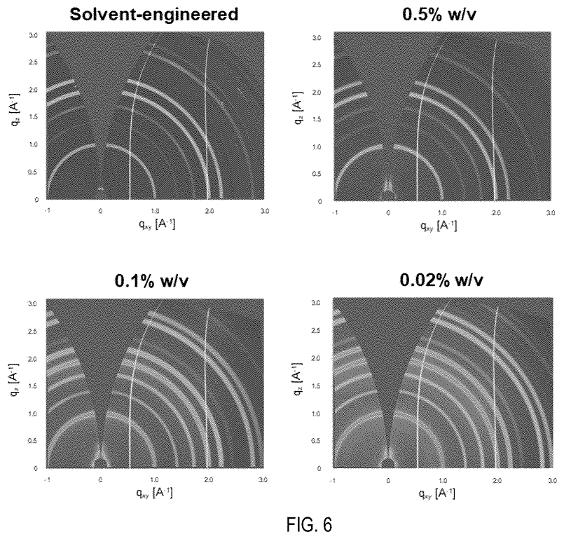

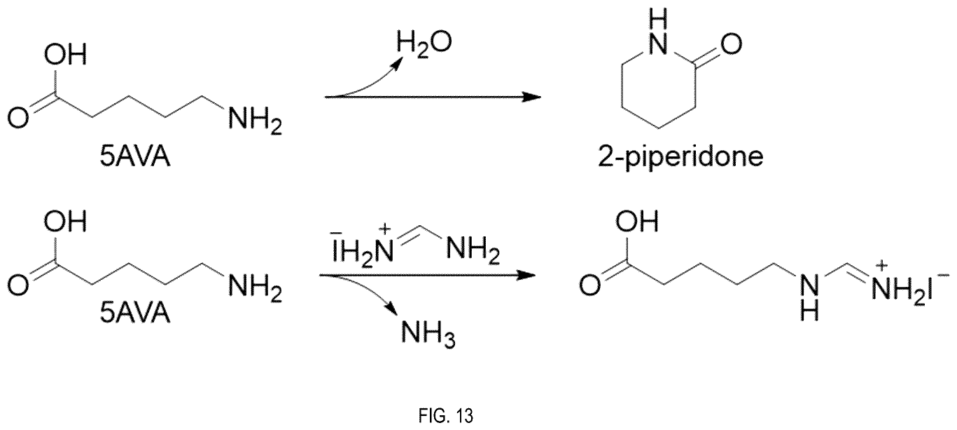

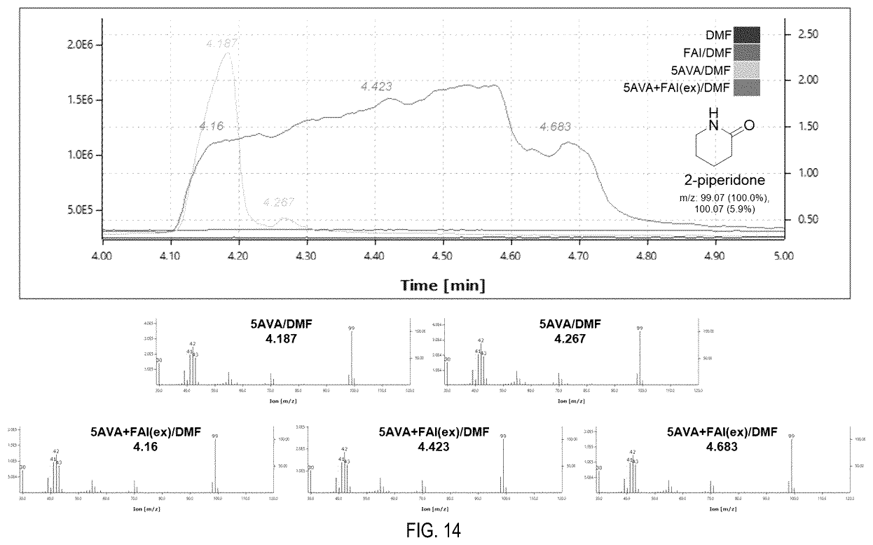

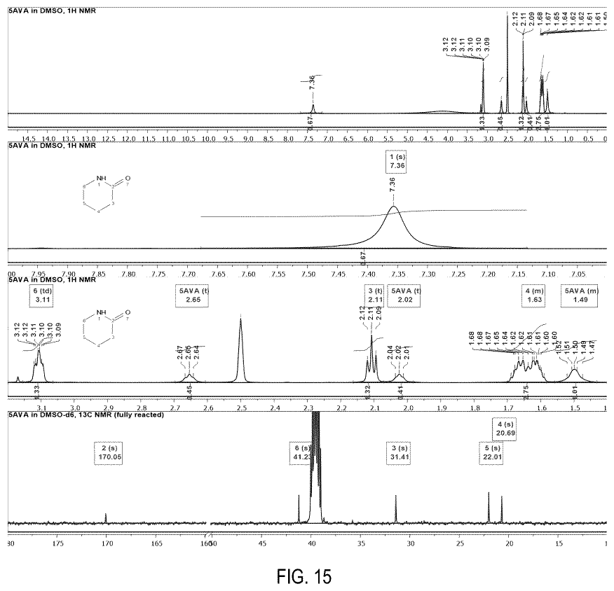

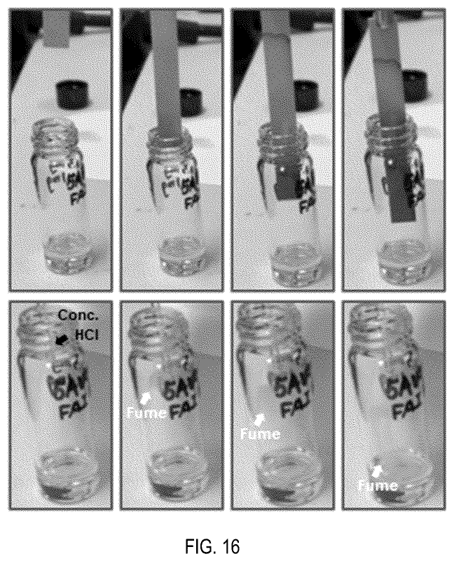

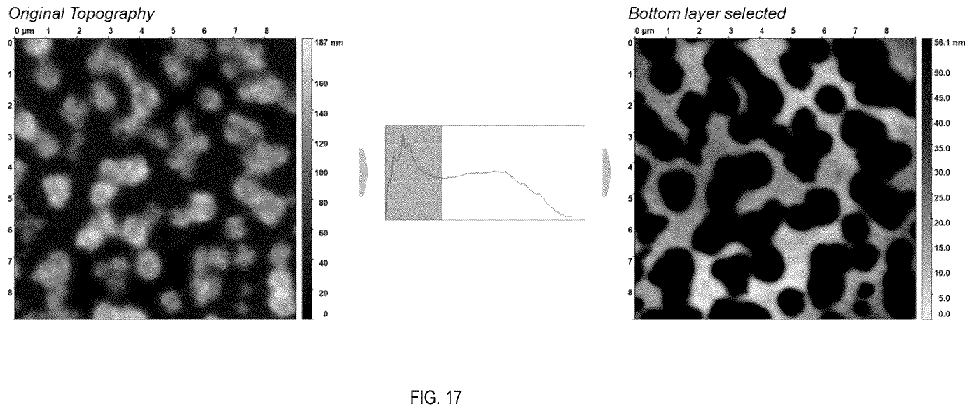

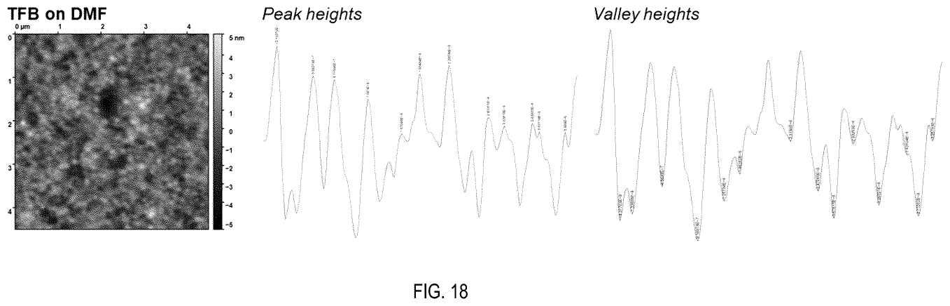

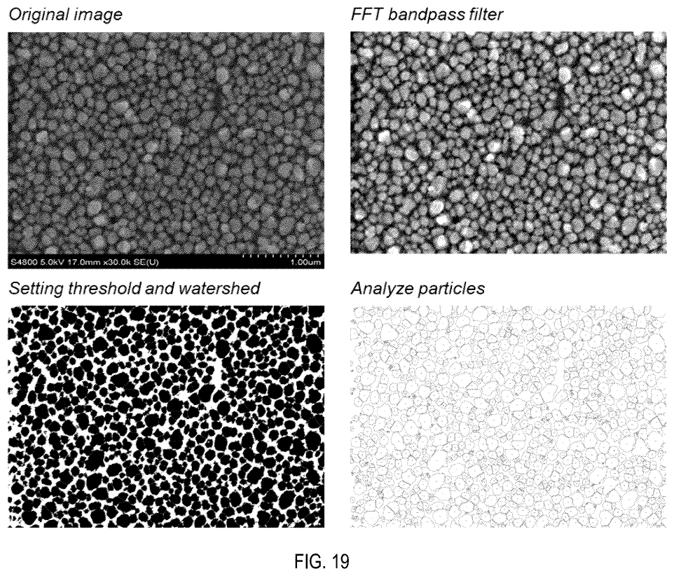

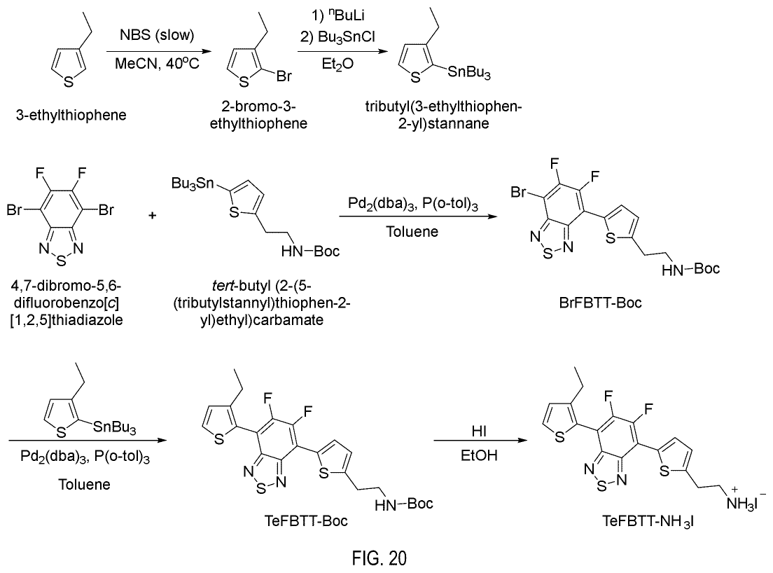

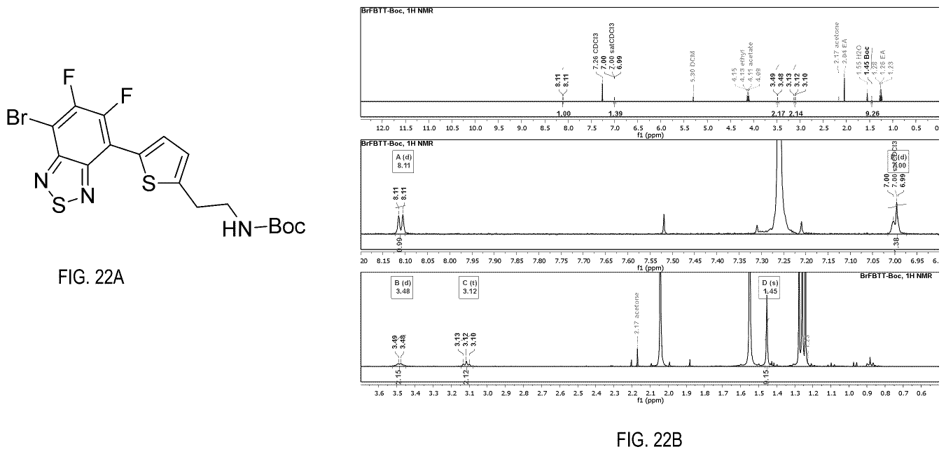

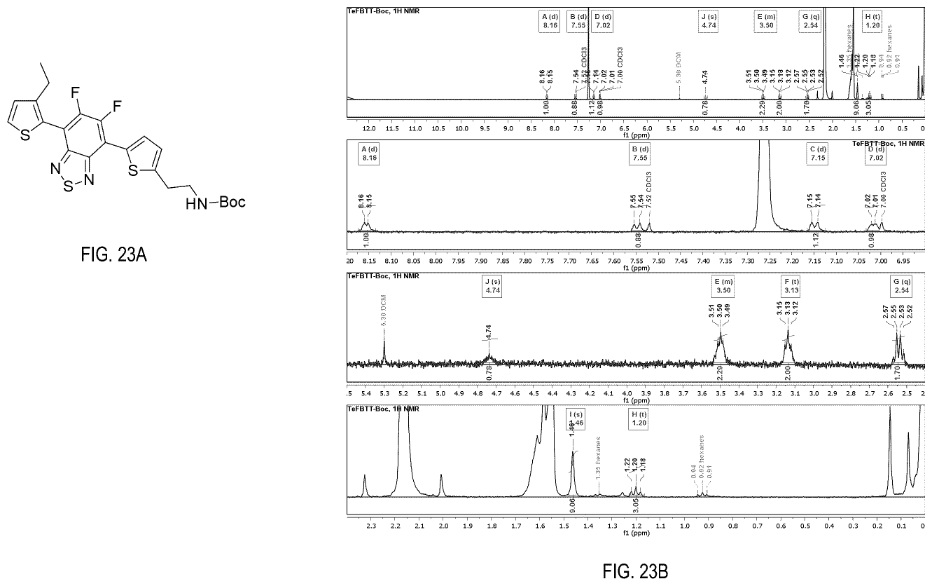

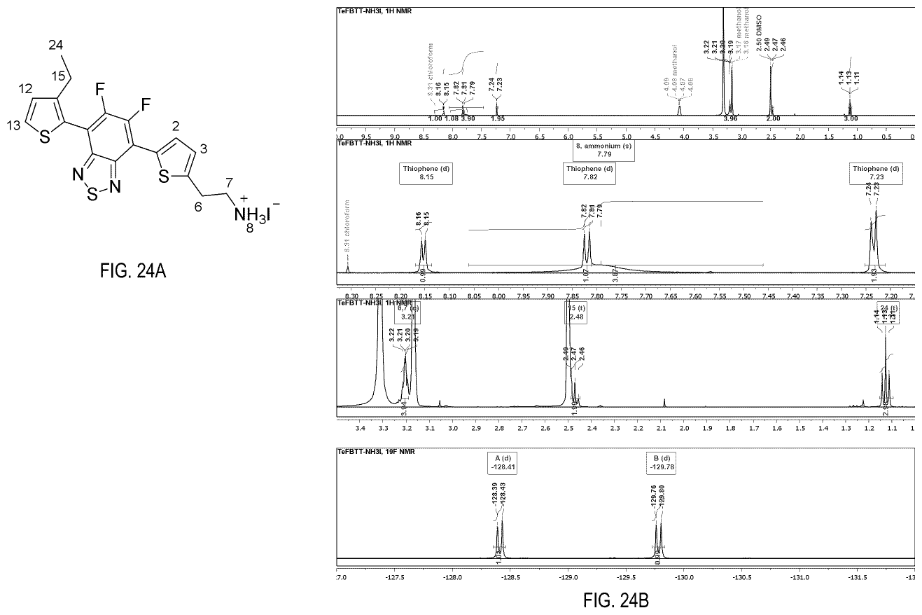

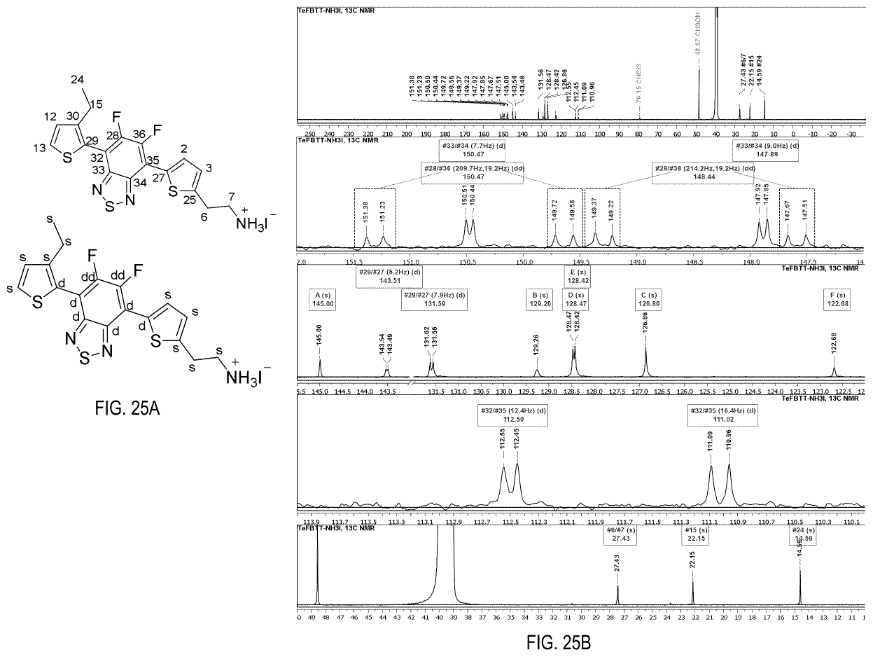

Additional information is shown in FIGS. 5-FIG. 25B. FIG. 5 shows AFM tomography of perovskite films with different solvent mixing ratios with line profiles included under each image. FIG. 6 shows GIWAXS patterns of perovskite films treated with different TeFBTT concentrations. FIGS. 7A-7F show PeLEDs with wide band-gap organic cations, in which FIG. 7A and FIG. 7B show J-V-R curves and EQE characteristics of PeLED with PEA, FIG. 7C and FIG. 7D show J-V-R curves and EQE characteristics of PeLED with 3T, and FIGS. 7E and 7F show the chemical structures of PeLED with PEA and with 3T. FIG. 8A and FIG. 8B, respectively, show J-V-R curves and EQE characteristics of PeLEDs from TeFBTT-treated devices. FIG. 9 shows the operational lifetime of PeLEDs with different current densities. FIGS. 10A-10C show discrete island—convex dome morphology under SEM and AFM, in which FIG. 10A shows cross-sectional SEM images of PeLEDs with varying solvent mixing ratios (scale bar: 400 nm), FIG. 10B shows AFM images, and FIG. 10C shows a height profile of TFB on perovskite films with varying solvent mixing ratios. FIG. 11 shows refractive index spectra of layers in PeLEDs obtained by ellipsometry, outcoupling efficiency was simulated based on refractive index at 800 nm. FIGS. 12A-12C, respectively, show histograms of nanoscale charge-carrier recombination lifetime mapping for control, solvent-engineered, and TeFBTT-treated films perovskite films. FIG. 13 shows a ring-closure lactam formation vs. reaction between 5AVA and FAI to form gaseous ammonia. FIG. 14 shows formation of 2-piperidone from 5AVA probed with GC-MS. FIG. 15 shows NMR spectra of 5AVA in DMSO in which the ¹H spectra were obtained before the complete reaction, while the ¹³C spectrum was obtained after the complete reaction. FIG. 16 shows a reaction between FAI and 5AVA in DMSO probed with (top) pH strips and (bottom) production of white fume with HCl vapor. FIG. 17 shows a representative topography from DMF:NMP=10:1. FIG. 18 shows a representative line profile extracted from topography image of TFB on perovskite with the DMF condition. FIG. 19 shows topography images obtained from SEM. FIG. 20 shows a synthetic scheme for TeFBTT. FIG. 21A and FIG. 21B, respectively, shows a 2-bromo-3-ethylthiophene structure and NMR spectra. FIG. 22A and FIG. 22B, respectively, show a (TeFBTT-Boc) tert-butyl (2-(5-(7-(3-ethylthiophen-2-yl)-5,6-difluorobenzo[c][1,2,5]thiadiazol-4-yl)thiophen-2-yl)ethyl)carbamate structure and NMR spectra. FIG. 23A and FIG. 23B, respectively, show a (BrFBTT-Boc) tert-butyl (2-(5-(7-bromo-5,6-difluorobenzo[c][1,2,5]thiadiazol-4-yl)thiophen-2-yl)ethyl)carbamate structure and NMR spectra. FIG. 24A and FIG. 24B, respectively, show a (TeFBTT, or TeFBTT-NH₃I) 2-(5-(7-(3-ethylthiophen-2-yl)-5,6-difluorobenzo[c][1,2,5]thiadiazol-4-yl)thiophen-2-yl)ethan-1-aminium iodide structure and NMR spectra. FIG. 25A and FIG. 25B, respectively, shows a ¹³C NMR (126 MHz, DMSO-d6) structure and NMR spectra.

### Solution Chemistry Between 5AVA and FAI

The procedure to synthesis polycrystalline perovskite films of 5AVA-modified FAPbI₃ is similar to known synthesis procedures. However, the solution chemistry involving 5AVA and FAI has not been elucidated before. FAPbI₃-based solar cells suggest a plausible reaction between primary amine and FAI to produce gaseous ammonium both in solution and solid state. Since the amino acid 5AVA is involved in the precursor solution used herein, a deailed analysis was conducted to unveil the solution chemistry between 5AVA and FAI. The results in this section indicated that 5AVA react with itself to form 2-piperidone in DMF or DMSO which protects itself from a further reaction with FAI. However, this formation of lactam competes with the as-predicted reaction between primary amine from 5AVA and FAI.

### Ring-Closure Lactam Formation

First, gas chromatography-mass spectra (GC-MS) were obtained from the DMF solution of 5AVA+5 equiv, in excess FAI mixture and compared with the those from the DMF solution of each individual component. Note, 5AVA itself has poor solubility in DMF without the presence of excess FAI. Thus, each solution/suspension studied were heated at 60° C. for 8 hours and filtered through a 0.22 μm syringe filter before GC-MS was conducted. The preparation of solutions were performed in a Na-filled glovebox to mimic the device fabrication process and prevent the impact from atmospheric O₂ and moisture. The initial concentration of 5AVA was kept at 0.1 M while the final concentration after filtration was unclear, except in the 5AVA-FAI mixture case where a clear solution could be obtained. Thus, the absolute peak intensity from GC was not quantitatively analyzed. This excessive heating condition was found to induce complete transition from 5AVA to 2-piperidone, as elaborated later.

As exhibited in FIG. 14, 2-piperidone was unambiguously identified from 5AVA/DMF solution. The presence of excess FAI in the solution were not able to consume 2-piperidone, indicating that the formation of lactam prevents any further reaction with FAI. However, the prestine 5AVA does not exist neither in the DMF solution of 5AVA itself nor with the presence of extra FAI.

Additionally, the ¹H and ¹³C NMR spectra of 5AVA in DMSO-d6 were obtained (FIG. 15). Note, 5AVA has higher solubility in DMSO than in DMF and a clear concentrated (ca. 0.1 M) solution of 5AVA in DMSO-d6 could be obtained with mild heating, and thus the spectra was obtained before complete consuption of 5AVA to form 2-piperidone. The ¹H signal from amide was clearly identified and correlated with other aliphatic ¹H signals from 2-piperidone. Aliphatic ¹H peaks from the leftover unreacted 5AVA were also identified. Furthermore, ¹³C NMR of a completely reacted solution indicated only the presence of 2-piperidone.

In summary, the combined results from GC-MS and NMR indicated that the self-reaction of 5AVA to form 2-piperidone take place in DMF or DMSO, driven by mild heating at 60° C. 2-piperidone is inert to further reaction with FAI.

### Formation of Gaseous Ammonia

To probe the formation of gaseous ammonia, 5AVA (14.3 mg) and FAI (140 mg) were dissolved in DMSO (1 mL). Upon mild heating at 60° C., production of the basic gas could be probed by a combination of pH strip test and HCl fuming test. The same phenomenon could be observed when the solution was prepared in a N₂-filled glovebox whether DMF or DMSO was used as solvents.

As 2-piperidone cannot react with FAI, the formation of gaseous ammonium is likely a result from the reaction between FAI and the primary amine in leftover 5AVA. Unfortunately, the targeted product predicted from Scheme 1 could not be identified from GC-MS.

Grain Analysis from SEM and AFM
Determining the Average Height (H) of Perovskite Layers from AFM Topography

Analysis in this section is related to FIG. 1A and FIG. 5. To determine H accurately the average height of the bottom layer as the baseline is subtracted from the average height of an AFM topography image. The discontinuous film morphology enables the extraction of this baseline by averaging the height from the “black voids”. As illustrated in FIG. 5 with a representative topography from the DMF:NMP=10:1 condition, selecting the topography below ca. 56 nm allows the determination of baseline height.

Analysis in this section is related to FIGS. 10A-10C and is used to determine the experimental/s for optical simulation in FIG. 4A. AFM tomography of the perovskite/TFB double layer is acquired, followed by extracting 10-line profiles from each profile. Each line profile contains the height variation on top of TFB layer created by the discontinuous film morphology of the underlying perovskite polycrystalline film.

FIG. 18 illustrates a representative line profile extracted from topography image of TFB on perovskite with the DMF condition (control). Height values of every peak and valley were obtained using the OriginLab software. The average hₛ is thus obtained by subtracting the mean valley height from the mean peak height.

Determining Average Grain Size and Packing Density (α) from SEM Topography

The packing density of each condition is included in FIG. 1A; the average grain size is used to construct the optical simulation model in FIG. 4A.

Particle analysis was conducted in the ImageJ software using the topography images obtained from SEM. The entire process is illustrated in FIG. 19 with the control film (DMF), which exhibited much higher a compared with solvent-engineered films (FIG. 1A) and made it most difficult to separate grains from each other. First, the original image was denoised with a Fast Fourier Transform (FFT) bandpass filter to select structures >5 pixels by removing noise signals at the high frequency regime. A threshold was then applied to the denoised image to differentiate grains from background. The binary image produced was applied with watershed function to automatically separate close grains that were not able to be separated by the threshold. Finally, the built-in analyze particle function was used to extract the average particle size and α.

### Refinement Details

The crystal under investigation was found to be non-merohedrally twinned. The orientation matrices for the two components were identified using the program Cell_Now, with the two components being related by a 180° rotation around the reciprocal a-axis. The transformation matrix found was:

$$[ \begin{matrix}1. & 0. & 0.685\end{matrix} ]$$

$$[ \begin{matrix}0. & - 1. & 0.\end{matrix} ]$$

$$[ \begin{matrix}0. & 0. & - 1.\end{matrix} ]$$

Integration proofed problematic due to excessive multiple overlap of reflections, resulting in large numbers of rejected reflections. Attempts were made to adjust integration parameters to avoid excessive rejections (through adjustments to integration queue size, integration box slicing and twin overlap parameters, and omission of box size optimization), which led to less but still substantial numbers of rejected reflections.

With no complete data set obtainable through simultaneous integration of both twin domains, the data were instead handled as if not twinned, with only the major domain integrated, and converted into an hklf 5 type format hkl file after integration using the “Make HKLF5 File” routine as implemented in WinGX. The twin law matrix was used as obtained from SAINT. The Overlap R1 and R2 values used were 0.45, i.e., reflections with a discriminator function less or equal to overlap radius of 0.45 were counted overlapped, all others as single. The discriminator function used was the “delta function on index non-integrality”. No reflections were omitted.

The structure was solved using direct methods with the hklf 4 type file and was refined using the hklf 5 type file, resulting in a BASF value of 0.261.

No Rint value is obtainable for the hklf 5 type file using the WinGX routine. The value from the dataset prior to correction for twinning is given instead.

The organic cation was found to be disordered by a rotation of the central PhN₂S ring, with the disorder extending to all other cation atoms other than the ammonium N atom. The two disordered moieties were restrained to have similar geometries, and chemically equivalent bonds were restrained to be similar. sp² hybridized segments of the cation were restrained to be close to planar. Uᵢⱼ components of ADPs for disordered atoms closer to each other than 2.0 Å were restrained to be similar. Subject to these conditions the occupancy ratio refined to 0.485-0.515.

No indication was found for presence of a larger unit cell ordered phase, or a lower symmetry ordered phase.

### Devices

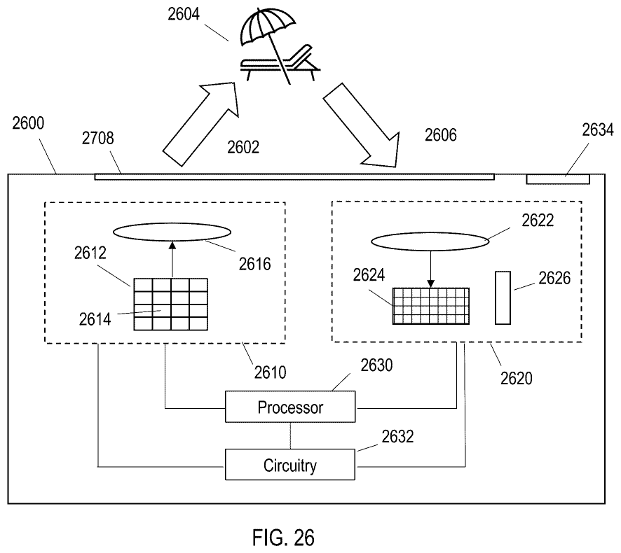

FIG. 26 shows a device, in accordance with some examples. The device 2600 may be, for example, a smart phone or standalone camera that contains a light source 2610 such as an array of PeLEDs described herein. The device 2600 may also include a camera 2620 that captures an image of a scene 2604 during an exposure duration of the camera 2620, whether or not the scene 2604 is illuminated by the light source 2610. A processor 2630 may be used to control various functions of the device 2600, including activation of the light source 2610 and the camera 2620 in addition to whether or not a shutter, disposed in an opening 2608 of a housing of the device 2600, is open.

The opening 2608 may be a single opening as shown in FIG. 26 or may include multiple separate openings. Similarly, the shutter may be a single shutter that covers both the light source 2610 and the camera 2620 or may include multiple separate shutters that covers only one of the light source 2610 or the camera 2620 and are individually controllable by the processor 2630.

The light source 2610 may include one or more LED arrays 2612 on a backplane such as a complementary metal oxide semiconductor (CMOS) or silicon (Si) backplane, for example. Each of the one or more LED arrays 2612 may include multiple LEDs 2614 that may produce visible and/or infrared light during at least a portion of the exposure duration of the camera 2620. At least some of the LEDs 2614 may be NIR PeLEDs for example.

Each LED 2614 or set of LEDs 2614 may form a pixel of the corresponding LED array 2612. LEDs 2614 may emit visible light (e.g., red, green, blue) or NIR light, as above. LEDs 2614 in a particular LED array 2612 that emit light in the infrared spectrum may be, for example, interspersed with LEDs 2614 that emit light in the visible spectrum, or each type of LED (visible emitter/infrared emitter) may be disposed on different sections of the particular LED array 2612.

Alternatively, each LED array 2612 may only emit light in either the visible spectrum or the infrared spectrum; separate (one or more) LED arrays may be used to emit light in the infrared spectrum. Each of the individual LED arrays 2612, LEDs 2614 within each LED array 2612, and/or groups of LEDs 2614 within each LED array 2614 (e.g., sets of 3×3 LEDs) may be individually controllable by the processor 2630.

The light source 2610 may include at least one lens 2616 and/or other optical elements such as reflectors. The lens 2616 and/or other optical elements may direct the light emitted by the one or more LED arrays 2612 toward the scene 2604 as illumination 2602. In some embodiments, reflectors may be disposed between adjacent pixels in the LED array 2612 or at the edges of the LED array 2612 to increase the light-extraction efficiency and provide beam shaping.

The camera 2620 may sense light at at least the wavelength or wavelengths emitted by the one or more LED arrays 2612. Similar to the light source 2610, the camera 2620 may include optics (e.g., at least one camera lens 2622) that are able to collect reflected light 2606 of the illumination 2602 that is reflected from and/or emitted by the scene 2604. The camera lens 2622 may direct the reflected light 2606 onto a light sensor 2624 to form an image of the scene 2604 on the light sensor 2624. The light sensor 2624 may contain multiple pixels to have a desired resolution (e.g., each pixel may correspond to a different LED 2614). In some embodiments, the light sensor 2624 may also be disposed on the CMOS or Si backplane.

The processor 2630 may control and drive the LEDs 2614 in the one or more LED arrays 2612 via circuitry 2632 that includes one or more drivers. For example, the processor 2630 may optionally control one or more LEDs 2614 in the one or more LED arrays 2612 independent of another one or more LEDs 2614 in the one or more LED arrays 2612, so as to illuminate the scene in a specified manner. The processor 2630 may also receive a data signal that represents the image of the scene 2604 and process the signal to adjust driving of the LEDs 2614 or otherwise adjust the image as desired.

In addition, one or more detectors 2626 may be incorporated in the camera 2620. In other embodiments, instead of being incorporated in the camera 2620, the one or more detectors 2626 may be incorporated in one or more different areas, such as the light source 2610 or elsewhere close to the camera 2620. The one or more detectors 2626 may include multiple different sensors to sense visible and/or infrared light (e.g., from the scene 2604), ambient light and/or variations/flicker in the ambient light in addition to reception of the reflected light from the LEDs 2614, or other actions, such as physical movement of the device 2600.

The light sensor 2624 of the camera 2620 may be of higher resolution than the sensors of the one or more detectors 2626 to obtain an image of the scene with a desired resolution. The sensors of the one or more detectors 2626 may have one or more segments (that are able to sense the same wavelength/range of wavelengths or different wavelength/range of wavelengths), similar to the LED arrays 2612. In some embodiments, if multiple detectors are used, one or more of the detectors may detect visible wavelengths and one or more of the detectors may detect infrared wavelengths; like the one or more LED arrays 2612, the one or more detectors 2626 may be individually controllable by the processor 2630.

In some embodiments, instead of, or in addition to, being provided in the camera 2620, one or more of the sensors of the one or more detectors 2626 may be provided in the light source 2610. In some embodiments, the light source 2610 and the camera 2620 may be integrated in a single module, while in other embodiments, the light source 2610 and the camera 2620 may be separate modules that are disposed on a PCB. In other embodiments, the light source 2610 and the camera 2620 may be attached to different PCBs—for example, as the camera 2620 may be thicker than the light source 2610, which may result in design issues if the light source 2610 and the camera 2620 are attached to the same PCB. In the latter embodiment, multiple openings may be present in the housing at least one of which may be eliminated with the use of an integrated light source 2610 and camera 2620.

The LEDs 2614 may be driven using a direct current (DC) driver or pulse width modulation (PWM) in the circuitry 2632. The LEDs 2614 may be driven using a PWM whose phase shift varies between LEDs 2614 to reduce potential current surge issues. As shown, the circuitry 2632 may include one or more drivers used to drive the LEDs 2614 in the one or more LED arrays 2612.

The device 2600 may also include an input device 2634, for example, a user-activated input device such as a button that is depressed to take a picture. The light source 2610 and camera 2620 may be disposed in a single housing.

As above, the light source 2610 of FIG. 26 may contain individually addressable LED segments to allow selective illumination of the scene 2604. For array sizes larger than 3×3 matrices, the LED segments may be combined with an integrated driver to allow the function of individual addressability and obtain the small form factor desired for mobile devices without creating issues in layout of the semiconductor layers used to create the integrated devices. LEDs can be used in the device 2600 shown in FIG. 26 to form different types of displays (e.g., smart phone displays, computer displays, smart watches, monitors, and TVs) and light engines including adaptive automotive headlights, AR, VR, or mixed-reality (MR) headsets, smart glasses, et al. The individual LED pixels in these architectures may have an area of few square millimeters down to few square micrometers depending on the matrix or display size and pixel-per-inch requirements.

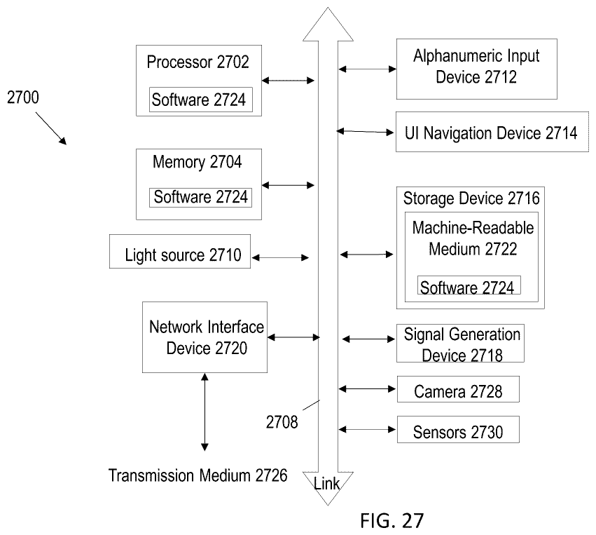

FIG. 27 illustrates an example of an electronic device in accordance with some embodiments. The electronic device 2700 may be, for example, a display, a monitor or screen, a wearable/mobile display device such as an AR/VR headset, a vehicular headlight, lighting for a particular area, or any other lighting arrangement. Various elements may be provided on a backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 2700 may include a hardware processor (or equivalently processing circuitry) 2702 (e.g., a central processing unit (CPU), a GPU, a hardware processor core, or any combination thereof), a memory 2704 (which may include main and static memory), some or all of which may communicate with each other via an interlink (e.g., bus) 2708. The memory 2704 may contain any or all of removable storage and non-removable storage, volatile memory or non-volatile memory. The electronic device 2700 may further include a light source 2710 such as the PeLEDs described herein, or a video display, an alphanumeric input device 2712 (e.g., a keyboard), and a user interface (UI) navigation device 2714 (e.g., a mouse). In an example, the light source 2710, input device 2712 and UI navigation device 2714 may be a touch screen display. The electronic device 2700 may additionally include a storage device (e.g., drive unit) 2716, a signal generation device 2718 (e.g., a speaker), a network interface device 2720, one or more cameras 2728, and one or more sensors 2730, such as a global positioning system (GPS) sensor, compass, accelerometer, or other sensor such as those described herein. The electronic device 2700 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). Some of the elements, such as one or more of the sparse arrays that provide the light source 2710 may be remote from other elements and may be controlled by the hardware processor 2702.

The storage device 2716 may be a non-transitory machine readable medium 2722 (hereinafter simply referred to as machine readable medium) on which is stored one or more sets of data structures or instructions 2724 (e.g., software) embodying or utilized by any one or more of the techniques or functions described herein. A storage device 2716 that includes the non-transitory machine-readable medium should not be construed as that either the device or the machine-readable medium is itself incapable of having physical movement. The instructions 2724 may also reside, completely or at least partially, within the memory 2704 and/or within the hardware processor 2702 during execution thereof by the electronic device 2700. While the machine readable medium 2722 is illustrated as a single medium, the term “machine readable medium” may include a single medium or multiple media (e.g., a centralized or distributed database, and/or associated caches and servers) configured to store the one or more instructions 2724.

The term “machine readable medium” may include any medium that can store, encode, or carry instructions for execution by the electronic device 2700 and that cause the electronic device 2700 to perform any one or more of the techniques of the present disclosure, or that can store, encode, or carry data structures used by or associated with such instructions. Non-limiting machine-readable medium examples may include solid-state memories, and optical and magnetic media. Specific examples of machine-readable media may include non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; Random Access Memory (RAM); and CD-ROM and DVD-ROM disks.

The instructions 2724 may further be transmitted or received over a communications network using a transmission medium 2726 via the network interface device 2720 utilizing any one of a number of wireless local area network (WLAN) transfer protocols or a SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 2702.11 family of standards known as Wi-Fi, IEEE 2702.14 family of standards known as WiMax, IEEE 2702.14.4 family of standards, a Long Term Evolution (LTE) family of standards, a Universal Mobile Telecommunications System (UMTS) family of standards, peer-to-peer (P2P) networks, a next generation (NG)/6^{th} generation (6G) standards among others. In an example, the network interface device 2720 may include one or more physical jacks (e.g., Ethernet, coaxial, or phone jacks) or one or more antennas to connect to the transmission medium 2726.

Note that the term “circuitry” as used herein refers to, is part of, or includes hardware components such as an electronic circuit, a logic circuit, a processor (shared, dedicated, or group) and/or memory (shared, dedicated, or group), an application-specific integrated circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical CPU, a single- or multi-core processor, and/or any other device capable of executing or otherwise operating computer-executable instructions, such as program code, software modules, and/or functional processes.

The camera 2728 may sense light at least the wavelength or wavelengths emitted by the LEDs. The camera 2728 may include optical elements (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 2702 may control and drive the LEDs via one or more drivers. For example, the processor 2702 may optionally control one or more LEDs in LED arrays independent of another one or more LEDs in the LED arrays, so as to illuminate an area in a specified manner.

In addition, the sensors 2730 may be incorporated in the camera 2728 and/or the light source 2710. The sensors 2730 may sense visible and/or infrared light or movement (e.g., via a gyroscope) among others. The sensors may have one or more segments (that are able to sense the same wavelength/range of wavelengths or different wavelength/range of wavelengths), similar to the LED arrays.

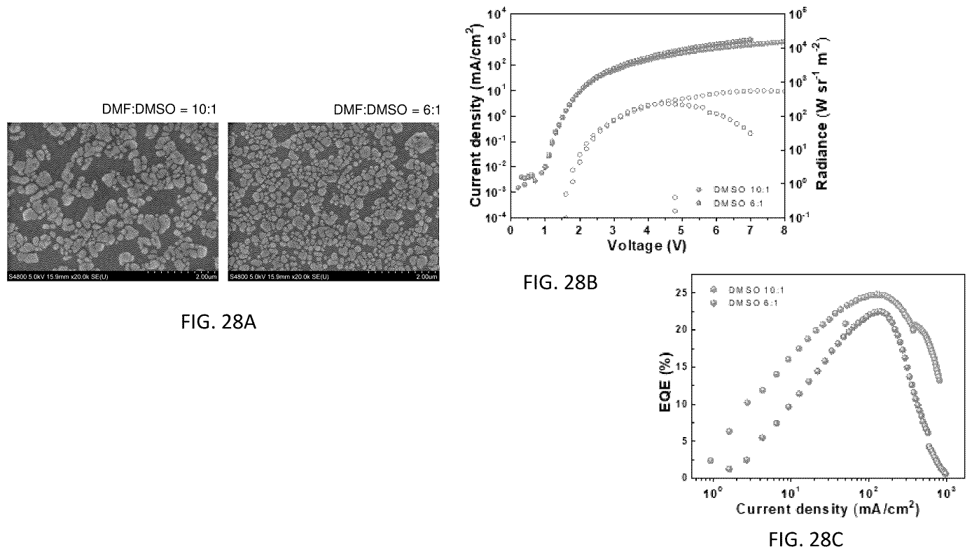

FIGS. 28A-FIG. 28C demonstrate the effects of the use of DMF with DMSO. FIG. 28A, FIG. 28B, and FIG. 28C, respectively, shows SEM images of perovskite films using DMF and DMSO solvent mixtures with different mixing ratios, J-V-R curves of PeLEDs with varying DMF and DMSO solvent mixing ratios, and EQE of PeLEDs with varying DMF and DMSO solvent mixing ratios. A ratio of DMF:DMSO in the mixture that provides a desirable reaction is between about 6:1 to about 10:1.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method of forming a near-infrared (NIR) perovskite light-emitting diode (PeLED), the method comprising:
dissolving perovskite precursors using a mixture of Lewis base solvents to form perovskite crystals, the mixture of Lewis base solvents comprising N,N-dimethylformamide (DMF) and at least one other Lewis base solvent selected from a group that includes N-methylpyrrolidone (NMP), dimethyl sulfoxide (DMSO), tris(N,N-tetramethylene) phosphoric acid triamide (TPPO), hexamethyl phosphoryl triamide (HMPA), diethyl sulfoxide (DES), N,N-dimethylpropyleneurea (DMPU), 1,3-dimethyl-2-imidazolidinone (DMI), N,N-dimethylacetamide (DMA), tetramethylene sulfoxide (TMSO), and 2-pyrrolidinone (PDI);
modifying the perovskite crystals using a small-bandgap organic cation of 2-(5-(7-(3-ethylthiophen-2-yl)-5,6-difluorobenzo[c][1,2,5]thiadiazol-4-yl)thiophen-2-yl)ethan-1-aminium iodide (TeFBTT) to form a two- or three-dimensional (2D/3D) perovskite heterostructure in a (TeFBTT)₂PbI₄ thin film; and
using the (TeFBTT)₂PbI₄ thin film to form the NIR PeLED.

2. The method of claim 1, wherein the at least one other Lewis base solvent is NMP and a ratio of DMF:NMP in the mixture is between about 10:1 to about 14:1.

3. The method of claim 1, wherein the at least one other Lewis base solvent is DMSO and a ratio of DMF:DMSO in the mixture is between about 6:1 to about 10:1.

4. The method of claim 1, wherein the TeFBTT includes a fluorinated benzothiadiazole (FBT) core with deep highest occupied molecular orbitals (HOMO) and lowest unoccupied molecular orbitals (LUMO) and a flexible ethyl side chain attached to a terminal thiophene to increase solubility and twist a backbone of the TeFBTT from a completely planar structure to form a torsion angle of 52° between FBT and the terminal thiophene.

5. The method of claim 3, wherein the NIR PeLED is post-treated with TeFBTT in an isopropanol (IPA)/chlorobenzene solution at a concentration of about 0.05% w/v to about 0.5% w/V.

6. The method of claim 1, wherein the 2D/3D perovskite heterostructure includes randomly distributed perovskite crystals that form convex structures and that function as isolated light emitters and light scatterers.

7. The method of claim 1, wherein the at least one other Lewis base solvent is NMP and the method further comprises preparing perovskite precursor solutions using FAI, PbI₂, and 5-aminovaleric acid (5AVA) with a molar ratio of about 2.5:1:0.7 dissolved in the DMF and NMP at about 60° C. for about two hours with stirring to maintain precursor concentrations of a resulting solution at about 10 wt %.

8. The method of claim 1, wherein fabricating the PeLED comprises:
depositing a zinc oxide (ZnO)/polyethylenimine ethoxylated (PEIE) layer on an indium-tin-oxide (ITO)-coated transparent substrate;
depositing the (TeFBTT)₂PbI₄ thin film on the ZnO/PEIE layer;
depositing a poly(9,9-dioctylfluorene-alt-N-(4-butylphenyl)-diphenylamine) (TFB) layer on the (TeFBTT)₂PbI₄ thin film;
depositing a molybdenum oxide (MoOₓ) layer on the TFB layer; and
depositing a gold (Au) layer on the MoOₓ layer to form a top electrode.

9. The method of claim 7, wherein the ITO-coated transparent substrate is about 120 nm, the ZnO-PEIE layer is about 30 nm, the TFB layer is about 50 nm, the MoOₓ layer is about 10 nm, and the Au layer is about 60 nm.

10. The method of claim 7, wherein the TFB layer does not make direct contact with the ZnO/PEIE layer.

11. The method of claim 7, wherein depositing the ZnO/PEIE layer comprises:
spin-coating ZnO nanocones (NCs) on the ITO-coated transparent substrate;
annealing the ZnO NCs,
spin-coating the PEIE layer on the ITO-coated transparent substrate containing the annealed ZnO NCs; and
annealing the PEIE layer on the ITO-coated transparent substrate.

12. A near-infrared (NIR) perovskite light emitting diode (PeLED) comprising:
a zinc oxide (ZnO)/polyethylenimine ethoxylated (PEIE) layer disposed on an indium-tin-oxide (ITO)-coated transparent substrate;
a 2-(5-(7-(3-ethylthiophen-2-yl)-5,6-difluorobenzo[c][1,2,5]thiadiazol-4-yl)thiophen-2-yl)ethan-1-aminium iodide (TeFBTT)PbI₄ thin film disposed on the ZnO/PEIE layer;
a poly(9,9-dioctylfluorene-alt-N-(4-butylphenyl)-diphenylamine) (TFB) layer disposed on the (TeFBTT)₂PbI₄ thin film;
a molybdenum oxide (MoOₓ) layer disposed on the TFB layer; and
a gold (Au) layer disposed on the MoOₓ layer to form a top electrode.

13. The NIR PeLED of claim 12, wherein the TeFBTT includes a fluorinated benzothiadiazole (FBT) core with deep highest occupied molecular orbitals (HOMO) and lowest unoccupied molecular orbitals (LUMO) and a flexible ethyl side chain attached to a terminal thiophene to increase solubility and twist a backbone of the TeFBTT from a completely planar structure to form a torsion angle of 52° between FBT and the terminal thiophene.

14. The NIR PeLED of claim 12, wherein the (TeFBTT)₂PbI₄ thin film contains a 2D/3D perovskite heterostructure that includes randomly distributed perovskite crystals that form convex structures and function as isolated light emitters and light scatterers, and the randomly distributed perovskite crystals have a convex dome morphology.

15. The NIR PeLED of claim 14, wherein the perovskite crystals are formed by dissolving perovskite precursors in a mixture of Lewis base solvents to form perovskite crystals, the mixture of Lewis base solvents comprising N,N-dimethylformamide (DMF) and at least one other Lewis base solvent selected from a group that includes N-methylpyrrolidone (NMP), dimethyl sulfoxide (DMSO), tris(N,N-tetramethylene) phosphoric acid triamide (TPPO), hexamethyl phosphoryl triamide (HMPA), diethyl sulfoxide (DES), N,N-dimethylpropyleneurea (DMPU), 1,3-dimethyl-2-imidazolidinone (DMI), N,N-dimethylacetamide (DMA), tetramethylene sulfoxide (TMSO), and 2-pyrrolidinone (PDI) at a ratio that is dependent on the at least one other Lewis base solvent.

16. The NIR PeLED of claim 15, wherein the at least one other Lewis base solvent is NMP and the perovskite crystals are formed by perovskite precursor solutions that use FAI, PbI₂, and 5-aminovaleric acid (5AVA) with a molar ratio of about 2.5:1:0.7 dissolved in the mixture of DMF and NMP.

17. The NIR PeLED of claim 12, wherein the ITO-coated transparent substrate is about 120 nm, the ZnO-PEIE layer is about 30 nm, the TFB layer is about 50 nm, the MoOₓ layer is about 10 nm, and the Au layer is about 60 nm.

18. The NIR PeLED of claim 12, wherein the TFB layer does not make direct contact with the ZnO/PEIE layer.

19. A method of forming a near-infrared (NIR) perovskite light emitting diode (PeLED), the method comprising:
dissolving perovskite precursors using a mixture of Lewis base solvents to form perovskite crystals, the mixture of Lewis base solvents comprising N,N-dimethylformamide (DMF) and at least one other Lewis base solvent selected from a group that includes N-methylpyrrolidone (NMP), dimethyl sulfoxide (DMSO), tris(N,N-tetramethylene) phosphoric acid triamide (TPPO), hexamethyl phosphoryl triamide (HMPA), diethyl sulfoxide (DES), N,N-dimethylpropyleneurea (DMPU), 1,3-dimethyl-2-imidazolidinone (DMI), N,N-dimethylacetamide (DMA), tetramethylene sulfoxide (TMSO), and 2-pyrrolidinone (PDI) at a ratio that is dependent on the at least one other Lewis base solvent;
modifying the perovskite crystals using a small-bandgap organic cation of 2-(5-(7-(3-ethylthiophen-2-yl)-5,6-difluorobenzo[c][1,2,5]thiadiazol-4-yl)thiophen-2-yl)ethan-1-aminium iodide (TeFBTT) to form a two- or three dimensional (2D/3D) perovskite heterostructure in a (TeFBTT)₂PbI₄ thin film; and
fabricating the PeLED using the (TeFBTT)₂PbI₄ thin film;
wherein the PeLED has a peak radiance and a peak external quantum efficiency (EQE) of at least about 500 W sr⁻¹ cm⁻² and at least about 26.5%, respectively.

20. The method of claim 19, wherein the at least one other Lewis base solvent is one of:
NMP and a ratio of DMF:NMP in the mixture is between about 10:1 to about 14:1, or
DMSO and a ratio of DMF:DMSO in the mixture is between about 6:1 to about 10:1.
